(19) United States
(12) Patent Application Publication
(10) Pub. No.: US 2026/0032811 A1
(43) Pub. Date: Jan. 29, 2026

(54) CIRCUIT BOARD

(71) Applicant: Murata Manufacturing Co., Ltd., Nagaokakyo-shi (JP)

(72) Inventor: Tomohiro FURUMURA, Nagaokakyo-shi (JP)

(21) Appl. No.: 19/343,266

(22) Filed: Sep. 29, 2025

Related U.S. Application Data
(63) Continuation of application No. PCT/JP2024/014342, filed on Apr. 9, 2024.

(30) Foreign Application Priority Data
Apr. 20, 2023 (JP) 2023-069297

(51) Int. Cl. H05K 1/02; H05K 1/11

(52) U.S. Cl. CPC H05K 1/0298; H05K 1/115; H05K 2201/09827

(57) ABSTRACT

A circuit board includes an insulating layer, first and second interlayer connection conductors penetrating an insulating layer in a thickness direction, first and second conductor layers respectively on first and second main surfaces of the insulating layer and connected to the first interlayer connection conductor, and third and fourth conductor layers respectively on the first and second main surfaces and connected to the second interlayer connection conductor. The first and second interlayer connection conductors respectively include first and second portions and third and fourth portions. When a height of the first portion is A₁, a height of the second portion is B₁, a height of the third portion is A₂, a height of the fourth portion is B₂, a height of the first interlayer connection conductor is T₁, and a height of the second interlayer connection conductor is T₂, relationships of T₁<T₂ and B₁/A₁>B₂/A₂ are satisfied.

### CROSS REFERENCE TO RELATED APPLICATIONS

This application claims the benefit of priority to Japanese Patent Application No. 2023-069297 filed on Apr. 20, 2023 and is a Continuation Application of PCT Application No. PCT/JP2024/014342 filed on Apr. 9, 2024. The entire contents of each application are hereby incorporated herein by reference.

### BACKGROUND OF THE INVENTION

### 1. Field of the Invention

The present invention relates to circuit boards.

### 2. Description of the Related Art

WO 2022/202322 A discloses a line board including an insulating layer and a conductor layer formed on one main surface of the insulating layer, in which the insulating layer includes a hole with the conductor layer as a bottom and opened toward the other main surface of the insulating layer, a first via portion connected to the conductor layer and a second via portion connected to the first via portion are provided in the hole, the first via portion includes a conductive member and does not include a resin member, the first via portion includes a protruding portion in which an end surface of the first via portion on a side of the second via portion protrudes toward the second via portion, a portion of the second via portion extends to between the protruding portion of the first via portion and the insulating layer, and is not in contact with the conductor layer connected to the first via portion.

WO 2022/202322 A describes that an interlayer connection conductor including a first via portion and a second via portion is provided by forming a first via portion partway through a hole by plating a hole provided in an insulating layer with conductor foil, and then forming a second via portion by filling a remaining portion of the hole in which the first via portion is formed with a conductive paste.

Further, WO 2022/202322 A describes that insulating layers including an insulating layer with conductor foil in which a first via portion and a second via portion are provided are sequentially stacked, and then the obtained stack is heat-pressed (collectively pressed) in a stacking direction to prepare a stacked substrate (hereinafter, also referred to as a multilayer circuit board).

However, since the second via portion formed by the solidification of the conductive paste has lower conductivity than the first via portion formed by filling with the plating metal, when the ratio of the second via portion to the interlayer connection conductor increases, the resistance value of the entire interlayer connection conductor increases, and thus the characteristics of the substrate may deteriorate.

### SUMMARY OF INVENTION

Example embodiments of the present invention provide circuit boards each able to reduce or prevent an increase in a resistance value of an entire interlayer connection conductor.

A circuit board according to an example embodiment of the present invention includes an insulating layer including a first main surface and a second main surface facing each other in a thickness direction, a first interlayer connection conductor and a second interlayer connection conductor penetrating a same insulating layer or different insulating layers in the thickness direction, a first conductor layer on the first main surface of the insulating layer and connected to the first interlayer connection conductor, a second conductor layer on the second main surface of the insulating layer and connected to the first interlayer connection conductor, a third conductor layer on the first main surface of the insulating layer and connected to the second interlayer connection conductor, and a fourth conductor layer on the second main surface of the insulating layer and connected to the second interlayer connection conductor. The first interlayer connection conductor includes a first portion and a second portion with lower conductivity than the first portion in the thickness direction. One end portion of the first portion is bonded to the first conductor layer, and an other end portion of the first portion is bonded to one end portion of the second portion. An other end portion of the second portion is bonded to the second conductor layer. The second interlayer connection conductor includes a third portion and a fourth portion with lower conductivity than the third portion in the thickness direction. One end portion of the third portion is bonded to the third conductor layer, and an other end portion of the third portion is bonded to one end portion of the fourth portion. An other end portion of the fourth portion is bonded to the fourth conductor layer. When a height of the first portion is A₁, a height of the second portion is B₁, a height of the third portion is A₂, a height of the fourth portion is B₂, a height of the first interlayer connection conductor is T₁, and a height of the second interlayer connection conductor is T₂, relationships of T₁<T₂ and B₁/A₁>B₂/A₂ are satisfied.

A circuit board according to another example embodiment of the present invention includes an insulating layer including a first main surface and a second main surface facing each other in a thickness direction, a first interlayer connection conductor and a third interlayer connection conductor penetrating a same insulating layer or different insulating layers in the thickness direction, a first conductor layer on the first main surface of the insulating layer and connected to the first interlayer connection conductor, a second conductor layer on the second main surface of the insulating layer and connected to the first interlayer connection conductor, a fifth conductor layer on the first main surface of the insulating layer and connected to the third interlayer connection conductor, and a sixth conductor layer on the second main surface of the insulating layer and connected to the fourth interlayer connection conductor. The first interlayer connection conductor includes a first portion and a second portion with lower conductivity than the first portion in the thickness direction. One end portion of the first portion is bonded to the first conductor layer, and an other end portion of the first portion is bonded to one end portion of the second portion. An other end portion of the second portion is bonded to the second conductor layer. The third interlayer connection conductor includes a fifth portion, a sixth portion with lower conductivity than the fifth portion, and a seventh portion with higher conductivity than the sixth portion in the thickness direction. One end portion of the fifth portion is bonded to the fifth conductor layer, and an other end portion of the fifth portion is bonded to one end portion of the sixth portion. An other end portion of the sixth portion is bonded to one end portion of the seventh portion. An other end portion of the seventh portion is bonded to the sixth conductor layer. When a height of the first portion is A₁, a height of the second portion is B₁, a height of the fifth portion is A₃, a height of the sixth portion is B₃, a height of the seventh portion is C₃, a height of the first interlayer connection conductor is T₁, and a height of the third interlayer connection conductor is T₃, relationships of T₁<T₃ and B₁/A₁>B₃/(A₃+C₃) are satisfied.

According to example embodiments of the present invention, circuit boards each able to reduce or prevent an increase in a resistance value of an entire interlayer connection conductor are provided.

The above and other elements, features, steps, characteristics and advantages of the present invention will become more apparent from the following detailed description of the example embodiments with reference to the attached drawings.

### BRIEF DESCRIPTION OF DRAWINGS

FIG. 1 is a cross-sectional view schematically illustrating an example of a circuit board according to an example embodiment of the present invention.

FIG. 2A is a cross-sectional view schematically illustrating an example of a circuit board according to a first example embodiment of the present invention. FIG. 2B is a cross-sectional view schematically illustrating an example of the circuit board at a position different from that in FIG. 2A.

FIGS. 3A and 3B are schematic views for explaining an example of a method of measuring a height of a first interlayer connection conductor, a height of a first portion, and a height of a second portion.

FIGS. 4A to 4D are cross-sectional views schematically illustrating an example of a step of preparing a first base filled with a first material and a second material.

FIGS. 5A to 5D are cross-sectional views schematically illustrating an example of a step of preparing a second base filled with a first material and a second material.

FIG. 6 is a cross-sectional view schematically illustrating an example of a step of stacking bases.

FIG. 7 is a cross-sectional view schematically illustrating an example of a step of collectively pressing.

FIG. 8A is a cross-sectional view schematically illustrating an example of a circuit board according to a second example embodiment of the present invention. FIG. 8B is a cross-sectional view schematically illustrating an example of the circuit board at a position different from that in FIG. 8A.

FIG. is a cross-sectional view schematically illustrating an example of a circuit board according to a third example embodiment of the present invention.

FIG. 10 is a cross-sectional view schematically illustrating another example of the circuit board according to a fourth example embodiment of the present invention.

FIG. 11 is a cross-sectional view schematically illustrating an example of a circuit board according to a fifth example embodiment of the present invention.

FIG. 12 is a cross-sectional view schematically illustrating another example of the circuit board according to the fifth example embodiment of the present invention.

FIG. 13A is a cross-sectional view schematically illustrating an example of a circuit board according to a sixth example embodiment of the present invention.

FIG. 13B is an example of an EBSD photograph showing an enlarged view of a circuit board according to the sixth example embodiment of the present invention.

FIG. 14A is a cross-sectional view schematically illustrating an example of a circuit board according to a seventh example embodiment of the present invention. FIG. 14B is a cross-sectional view schematically illustrating an example of the circuit board at a position different from that in FIG. 14A.

FIG. 15 is a cross-sectional view schematically illustrating an example of a circuit board according to an eighth example embodiment of the present invention.

FIG. 16 is cross-sectional view schematically illustrating an example of a circuit board according to a ninth example embodiment of the present invention.

FIG. 17 is a cross-sectional view schematically illustrating another example of the circuit board according to the ninth example embodiment of the present invention.

FIGS. 18A to 18C are cross-sectional views schematically illustrating an example of a circuit board according to a tenth example embodiment of the present invention.

FIG. 19A is a cross-sectional view schematically illustrating an example of a circuit board according to an eleventh example embodiment of the present invention. FIG. 19B is a cross-sectional view schematically illustrating an example of the circuit board at a position different from that in FIG. 19A.

FIG. 20 is a cross-sectional view schematically illustrating an example of a circuit module including a circuit board according to an example embodiment of the present invention.

FIG. 21 is a plan view schematically illustrating an example of a surface layer of a circuit board according to an example embodiment of the present invention.

FIGS. 22A to 22C are cross-sectional views schematically illustrating examples of interlayer connection conductors with a constant height and different diameters.

FIGS. 23A and 23B are examples of SEM photographs showing interlayer connection conductors of different heights.

### DETAILED DESCRIPTION OF THE EXAMPLE EMBODIMENTS

Hereinafter, circuit boards according to example embodiments of the present invention will be described in detail with reference to the drawings.

However, the present invention is not limited to the following configurations, and changes can be appropriately applied thereto within a range not changing the gist of the present invention. The present invention also includes a combination of two or more of the individual example embodiments of the present invention described below.

In the present specification, the term (for example, “vertical”, “parallel”, “orthogonal”, and the like) indicating the relationship between elements and the term indicating the shape of an element are not expressions indicating only a strict meaning, but are expressions that include a substantially equivalent range, for example, a difference of about several %. In addition, in the present specification, “equivalent” is not an expression meaning only a case of being exactly equivalent, but is an expression including a case of being substantially equivalent includes, for example, a difference of about several %.

The drawings are schematic views, and dimensions, scales of aspect ratios, and the like may be different from those of actual products. In the drawings, the same or corresponding portions are denoted by the same reference numerals. In each drawing, the same or corresponding elements are denoted by the same reference numerals, and redundant description will be omitted.

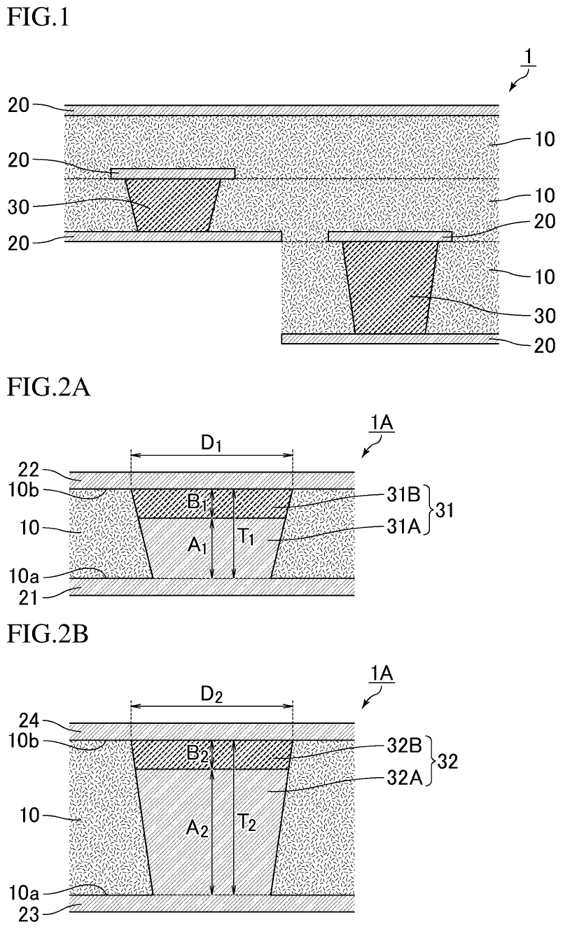

FIG. 1 is a cross-sectional view schematically illustrating an example of a circuit board according to an example embodiment of the present invention.

A circuit board 1 illustrated in FIG. 1 includes an insulating layer 10, a conductor layer 20, and an interlayer connection conductor 30.

In the example illustrated in FIG. 1, the circuit board 1 is a multilayer circuit board including a plurality of insulating layers 10.

The circuit board 1 may be a rigid board or a flexible board. The circuit board 1 may include a bent portion.

In the circuit board 1, the conductor layer 20 includes a first conductor layer, a second conductor layer, a third conductor layer, and a fourth conductor layer described in the following example embodiments. The conductor layer 20 may include a fifth conductor layer and a sixth conductor layer in addition to the first conductor layer, the second conductor layer, the third conductor layer, and the fourth conductor layer. Alternatively, the conductor layer 20 may include the fifth conductor layer and the sixth conductor layer instead of the third conductor layer and the fourth conductor layer. The circuit board 1 may include a conductor layer 20 other than the first conductor layer, the second conductor layer, the third conductor layer, the fourth conductor layer, the fifth conductor layer, and the sixth conductor layer.

In the circuit board 1, the interlayer connection conductor 30 includes a first interlayer connection conductor and a second interlayer connection conductor described in each example embodiment described below. Specifically, it is sufficient that at least one first interlayer connection conductor and at least one second interlayer connection conductor are included in the circuit board 1.

The interlayer connection conductor 30 may include a third interlayer connection conductor in addition to the first interlayer connection conductor and the second interlayer connection conductor. Specifically, at least one first interlayer connection conductor, at least one second interlayer connection conductor, and at least one third interlayer connection conductor may be included in the circuit board 1.

Alternatively, the interlayer connection conductor 30 may include the third interlayer connection conductor instead of the second interlayer connection conductor. Specifically, at least one first interlayer connection conductor and at least one third interlayer connection conductor may be included in the circuit board 1.

The circuit board 1 may include an interlayer connection conductor 30 other than the first interlayer connection conductor, the second interlayer connection conductor, and the third interlayer connection conductor.

Each example embodiment of the present invention described below is an example, and partial replacement or combination of configurations illustrated in different example embodiments is possible. In the second and subsequent example embodiments, descriptions of matters common to the first example embodiment will be omitted, and only differences will be described. In particular, the same operation and advantageous effects by the same configuration will not be sequentially described for each example embodiment.

FIG. 2A is a cross-sectional view schematically illustrating an example of a circuit board according to a first example embodiment of the present invention. FIG. 2B is a cross-sectional view schematically illustrating an example of the circuit board at a position different from that in FIG. 2A.

Although the overall configuration is not illustrated in FIGS. 2A and 2B, a circuit board 1A includes an insulating layer 10, a first conductor layer 21, a second conductor layer 22, a third conductor layer 23, a fourth conductor layer 24, a first interlayer connection conductor 31, and a second interlayer connection conductor 32.

The insulating layer 10 includes a first main surface 10a and a second main surface 10b facing each other in the thickness direction (the vertical direction in FIGS. 2A and 2B).

The insulating layer 10 is, for example, a resin insulating layer including a resin as a main component. In a case where the first conductor layer 21 or the second conductor layer 22 is a signal line, or in a case where the third conductor layer 23 or the fourth conductor layer 24 is a signal line, for example, a resin with a low dielectric constant is included in the insulating layer 10, so that loss at the time of signal transmission can be reduced.

Alternatively, the insulating layer 10 may be, for example, a ceramic insulating layer including ceramic as a main component. In a case where the first conductor layer 21 or the second conductor layer 22 is an antenna electrode, or in a case where the third conductor layer 23 or the fourth conductor layer 24 is an antenna electrode, a ceramic with a high dielectric constant is included in the insulating layer 10, so that radiation or reception can be performed in a wide band.

The resin of the resin insulating layer may be, for example, a thermosetting resin or a thermoplastic resin, but is preferably a thermoplastic resin. In a case where the resin insulating layer is made of a thermoplastic resin, a plurality of resin sheets on which the conductor layer is formed can be stacked, and collectively press-bonded (collectively pressed) by heat treatment.

Examples of the thermosetting resin include an epoxy resin, a phenol resin, a polyimide resin or a modified resin thereof, or an acrylic resin.

Examples of the thermoplastic resin include a liquid crystal polymer (LCP), a fluororesin, a thermoplastic polyimide resin, a polyether ether ketone resin (PEEK), or a polyphenylene sulfide resin (PPS).

The resin insulating layer is preferably made of liquid crystal polymer (LCP), for example. Liquid crystal polymers have lower water absorption than other thermoplastic resins. Therefore, when the resin insulating layer is made of a liquid crystal polymer, moisture remaining in the resin insulating layer can be reduced.

The resin insulating layer may include an inorganic material such as a ceramic filler, for example.

Examples of the ceramic filler include boron nitride, talc, or fused silica.

Examples of the ceramic of the ceramic insulating layer include a low-temperature co-fired ceramic (LTCC) or a high-temperature co-fired ceramic (HTCC).

The thickness of one layer of the insulating layer 10 is, for example, preferably about 10 μm or more and about 100 μm or less.

The first conductor layer 21 is provided on the first main surface 10a of the insulating layer 10 and is connected to the first interlayer connection conductor 31.

The second conductor layer 22 is provided on the second main surface 10b of the insulating layer 10 and is connected to the first interlayer connection conductor 31.

Each of the first conductor layer 21 and the second conductor layer 22 may have a patterned shape obtained by patterning the layer into lines, for example, or may have a planar shape spread over one surface. The shapes of the first conductor layer 21 and the second conductor layer 22 may be the same or substantially the same as or different from each other.

Each of the first conductor layer 21 and the second conductor layer 22 is, for example, a metal layer including at least one of copper, silver, aluminum, stainless steel, nickel, gold, or these metals. The materials of the first conductor layer 21 and the second conductor layer 22 may be the same as or different from each other. Both of the first conductor layer 21 and the second conductor layer 22 are, for example, preferably made of a metal foil, and more preferably made of a copper (Cu) foil.

Each of the first conductor layer 21 and the second conductor layer 22 may have a mat surface on one main surface and a shiny surface on the other main surface.

The thickness (length in the stacking direction) of each of the first conductor layer 21 and the second conductor layer 22 is, for example, preferably about 1 μm or more and about 35 μm or less, and more preferably about 6 μm or more and about 18 μm or less. The thickness of the first conductor layer 21 and the second conductor layer 22 may be the same or substantially the same as or different from each other.

The first conductor layer 21 and the second conductor layer 22 may or may not be parallel or substantially parallel to each other.

One insulating layer 10 may be provided between the first conductor layer 21 and the second conductor layer 22, or two or more insulating layers 10 may be provided therebetween. When two or more insulating layers 10 are provided between the first conductor layer 21 and the second conductor layer 22, the configurations of the insulating layers 10 may be the same or substantially the same as or different from each other. In addition, when two or more insulating layers 10 are provided between the first conductor layer 21 and the second conductor layer 22, the thickness of the insulating layers 10 may be the same or substantially the same as or different from each other.

The third conductor layer 23 is provided on the first main surface 10a of the insulating layer 10 and is connected to the second interlayer connection conductor 32.

The fourth conductor layer 24 is provided on the second main surface 10b of the insulating layer 10 and is connected to the second interlayer connection conductor 32.

Each of the third conductor layer 23 and the fourth conductor layer 24 may have a patterned shape obtained by patterning the layer into lines, for example, or may have a planar shape spread over one surface. The shapes of the third conductor layer 23 and the fourth conductor layer 24 may be the same or substantially the same as or different from each other.

Each of the third conductor layer 23 and the fourth conductor layer 24 is, for example, a metal layer including at least one of copper, silver, aluminum, stainless steel, nickel, gold, or these metals. The materials of the third conductor layer 23 and the fourth conductor layer 24 may be the same as or different from each other. Each of the third conductor layer 23 and the fourth conductor layer 24 is, for example, preferably made of a metal foil, and more preferably made of a copper (Cu) foil.

Each of the third conductor layer 23 and the fourth conductor layer 24 may have a mat surface on one main surface and a shiny surface on the other main surface.

The thickness (length in the stacking direction) of each of the third conductor layer 23 and the fourth conductor layer 24 is, for example, preferably about 1 μm or more and about 35 μm or less, and more preferably about 6 μm or more and about 18 μm or less. The thickness of the third conductor layer 23 and the fourth conductor layer 24 may be the same or substantially the same as or different from each other.

The third conductor layer 23 and the fourth conductor layer 24 may or may not be parallel or substantially parallel to each other.

One insulating layer 10 may be provided between the third conductor layer 23 and the fourth conductor layer 24, or two or more insulating layers 10 may be provided therebetween. When two or more insulating layers 10 are provided between the third conductor layer 23 and the fourth conductor layer 24, the configurations of the insulating layers 10 may be the same or substantially the same as or different from each other. In addition, when two or more insulating layers 10 are provided between the third conductor layer 23 and the fourth conductor layer 24, the thickness of the insulating layers 10 may be the same or substantially the same as or different from each other.

The first interlayer connection conductor 31 and the second interlayer connection conductor 32 penetrate the insulating layer 10 in the thickness direction.

The first interlayer connection conductor 31 is connected to the first conductor layer 21 and the second conductor layer 22 while penetrating the insulating layer 10 in the thickness direction but not penetrating the first conductor layer 21 and the second conductor layer 22. Therefore, the first interlayer connection conductor 31 penetrates the insulating layer(s) 10 in the thickness direction by the number of layers provided between the first conductor layer 21 and the second conductor layer 22. For example, the first interlayer connection conductor 31 penetrates one insulating layer 10 in the thickness direction.

The second interlayer connection conductor 32 is connected to the third conductor layer 23 and the fourth conductor layer 24 while penetrating the insulating layer 10 in the thickness direction but not penetrating the third conductor layer 23 and the fourth conductor layer 24. Therefore, the second interlayer connection conductor 32 penetrates the insulating layer(s) 10 in the thickness direction by the number of layers provided between the third conductor layer 23 and the fourth conductor layer 24. For example, the second interlayer connection conductor 32 penetrates one insulating layer 10 in the thickness direction.

The insulating layer 10 provided with the first interlayer connection conductor 31 may be the same layer as or different from the insulating layer 10 provided with the second interlayer connection conductor 32, but is preferably a different layer. In this case, the thickness of the insulating layer 10 provided with the first interlayer connection conductor 31 is preferably smaller than the thickness of the insulating layer 10 provided with the second interlayer connection conductor 32.

For example, when the circuit board 1A is a multilayer circuit board including a plurality of insulating layers 10, the insulating layer 10 provided with the first interlayer connection conductor 31 is preferably a layer different from the insulating layer 10 provided with the second interlayer connection conductor 32 in the thickness direction. In this case, the insulating layer 10 provided with the first interlayer connection conductor 31 and the insulating layer 10 provided with the second interlayer connection conductor 32 may be adjacent to each other in the thickness direction, and at least one insulating layer 10 may be disposed between the insulating layer 10 provided with the first interlayer connection conductor 31 and the insulating layer 10 provided with the second interlayer connection conductor 32.

In a cross section perpendicular or substantially perpendicular to the thickness direction, the shapes of the first interlayer connection conductor 31 and the second interlayer connection conductor 32 are preferably circular. In this case, not only a perfect circle but also an ellipse, an oval, and the like are included in the circle. The cross-sectional shapes of the first interlayer connection conductor 31 and the second interlayer connection conductor 32 may be the same or substantially the same as or different from each other.

The first interlayer connection conductor 31 includes a first portion 31A and a second portion 31B in the thickness direction.

The first portion 31A is, for example, a plated via.

Here, the plating via means a film grown by a liquid phase method or a gas phase method.

When the first portion 31A is a plated via, the metal included in the first portion 31A is preferably the same as the metal included the first conductor layer 21, and is, for example, Cu.

The second portion 31B has lower conductivity than the first portion 31A.

The second portion 31B is, for example, a paste via. Here, the paste via means a solidified paste. When the circuit board 1A is manufactured by collective pressing described later, the second portion 31B defines and functions as a bonding material, so that the first portion 31A and the second conductor layer 22 can be conductively connected.

When the second portion 31B is a paste via, examples of the metal included in the second portion 31B include Cu, Sn, Ag, Ni, Cr, Pt, Mo, Ga, Ge, Sb, In, Pb, or an alloy including at least one of these metals. The metal included in the second portion 31B may be the same as or different from the metal included in the first portion 31A. The metal included in the second portion 31B is, for example, an alloy including Cu and Sn.

Alternatively, the second portion 31B may be a plated via.

When the second portion 31B is a plated via, examples of the metal included in the second portion 31B include Sn. By using Sn having a low melting point, it is easy to cause the second portion 31B to define and function as a bonding material.

One end portion of the first portion 31A is bonded to the first conductor layer 21, and the other end portion of the first portion 31A is bonded to one end portion of the second portion 31B.

The first portion 31A and the first conductor layer 21 are directly bonded without interposing a dissimilar material therebetween. Therefore, at the interface between the first portion 31A and the first conductor layer 21, there is a portion where different materials do not exist, that is, a portion where the first portion 31A and the first conductor layer 21 are in direct contact with each other.

The other end portion of the second portion 31B is bonded to the second conductor layer 22.

The second interlayer connection conductor 32 includes a third portion 32A and a fourth portion 32B in the thickness direction.

The third portion 32A is, for example, a plated via.

When the third portion 32A is a plated via, the metal included in the third portion 32A is preferably the same as the metal constituting the third conductor layer 23, and is, for example, Cu. The metal included in the third portion 32A is preferably the same as the metal included in the first portion 31A.

The fourth portion 32B has lower conductivity than the third portion 32A.

The fourth portion 32B is, for example, a paste via. When the circuit board 1A is manufactured by collective pressing described later, the fourth portion 32B defines and functions as a bonding material, so that the third portion 32A and the fourth conductor layer 24 can be conductively connected.

When the fourth portion 32B is a paste via, examples of the metal included in the fourth portion 32B include Cu, Sn, Ag, Ni, Cr, Pt, Mo, Ga, Ge, Sb, In, Pb, or an alloy including at least one of these metals. The metal included in the fourth portion 32B may be the same as or different from the metal included in the third portion 32A. The metal included in the fourth portion 32B is, for example, an alloy including Cu and Sn. The metal included in the fourth portion 32B is preferably the same as the metal included in the second portion 31B.

Alternatively, the fourth portion 32B may be a plated via.

When the fourth portion 32B is a plated via, examples of the metal included in the fourth portion 32B include Sn. By using Sn having a low melting point, it is easy to cause the fourth portion 32B to define and function as a bonding material. The metal included in the fourth portion 32B is preferably the same as the metal included in the second portion 31B.

One end portion of the third portion 32A is bonded to the third conductor layer 23, and the other end portion of the third portion 32A is bonded to one end portion of the fourth portion 32B.

The third portion 32A and the third conductor layer 23 are directly bonded without interposing a dissimilar material therebetween. Therefore, at the interface between the third portion 32A and the third conductor layer 23, there is a portion where different materials do not exist, that is, a portion where the third portion 32A and the third conductor layer 23 are in direct contact with each other.

The other end portion of the fourth portion 32B is bonded to the fourth conductor layer 24.

As illustrated in FIGS. 2A and 2B, when the height of the first portion 31A is A₁, the height of the second portion 31B is B₁, the height of the third portion 32A is A₂, the height of the fourth portion 32B is B₂, the height of the first interlayer connection conductor 31 is T₁, and the height of the second interlayer connection conductor 32 is T₂, relationships of T₁<T₂ and B₁/A₁>B₂/A₂ are satisfied.

That is, among the first interlayer connection conductor 31 and the second interlayer connection conductor 32, in the second interlayer connection conductor 32 having a large height, a ratio of a portion having low conductivity is smaller than that of the first interlayer connection conductor 31 having a small height. As a result, even when interlayer connection conductors having different heights are included, an increase in the resistance value of the entire interlayer connection conductor can be reduced or prevented.

On the other hand, among the first interlayer connection conductor 31 and the second interlayer connection conductor 32, in the first interlayer connection conductor 31 having a small height, a ratio of a portion having high conductivity is smaller than that of the second interlayer connection conductor 32 having a large height. For example, in a case where the first portion 31A is a plated via and the second portion 31B is a paste via, an increase in manufacturing cost can be reduced or prevented by not forming the first portion 31A more than necessary.

The height B₁ of the second portion 31B is preferably equal or substantially equal to the height B₂ of the fourth portion 32B. As long as the relationships of T₁<T₂ and B₁/A₁>B₂/A₂ are satisfied, the height B₁ of the second portion 31B may be greater than the height B₂ of the fourth portion 32B, and may be smaller than the height B₂ of the fourth portion 32B.

The diameter of the first interlayer connection conductor 31 is preferably smaller than the diameter of the second interlayer connection conductor 32. As long as the relationships of T₁<T₂ and B₁/A₁>B₂/A₂ are satisfied, the diameter of the first interlayer connection conductor 31 may be equal or substantially equal to the diameter of the second interlayer connection conductor 32, or may be greater than the diameter of the second interlayer connection conductor 32.

There may be two or more types of the first interlayer connection conductors 31 having the height T₁ and different diameters. In this case, the height A₁ of the first portion 31A of the first interlayer connection conductor 31 having a larger diameter is preferably smaller than the height A₁ of the first portion 31A of the first interlayer connection conductor 31 having a smaller diameter.

Similarly, there may be two or more types of the second interlayer connection conductors 32 having the height T₂ and different diameters. In this case, the height A₂ of the third portion 32A of the second interlayer connection conductor 32 having a larger diameter is preferably smaller than the height A₂ of the third portion 32A of the second interlayer connection conductor 32 having a smaller diameter.

As long as the relationships of T₁<T₂ and B₁/A₁>B₂/A₂ are satisfied, the height A₁ of the first portion 31A may be equal or substantially equal to the height B₁ of the second portion 31B, and may be less than the height B₁ of the second portion 31B (A₁<B₁), but is preferably higher than the height B₁ of the second portion 31B (A₁>B₁). In particular, when the first interlayer connection conductor 31 has a tapered shape, the connection area between the first portion 31A and the second portion 31B is increased by making the height A₁ of the first portion 31A higher than the height B₁ of the second portion 31B, so that the connection reliability of the first interlayer connection conductor 31 can be improved.

Similarly, as long as the relationships of T₁<T₂ and B₁/A₁>B₂/A₂ are satisfied, the height A₂ of the third portion 32A may be equal or substantially equal to the height B₂ of the fourth portion 32B, and may be lower than the height B₂ of the fourth portion 32B (A₂<B₂), but is preferably higher than the height B₂ of the fourth portion 32B (A₂>B₂). In particular, when the second interlayer connection conductor 32 has a tapered shape, the connection area between the third portion 32A and the fourth portion 32B is increased by making the height A₂ of the third portion 32A higher than the height B₂ of the fourth portion 32B, so that the connection reliability of the second interlayer connection conductor 32 can be improved.

The shape of the first interlayer connection conductor 31 is not limited to FIG. 2A.

The second portion 31B may have a tapered shape in which the area of the end surface on the first conductor layer 21 side is smaller than the area of the end surface on the second conductor layer 22 side. The connection strength between the second portion 31B and the second conductor layer 22 can be increased by increasing the area of the second portion 31B at the portion connected to the second conductor layer 22.

When the second portion 31B has a tapered shape, the inclination angle of the tapered shape may be different stepwise. In this case, the connection strength between the second portion 31B and the second conductor layer 22 can be further increased. The inclination angle of the tapered shape may change in two stages, may change in three stages, or may change in four or more stages.

Furthermore, the first portion 31A may have a tapered shape in which the area of the end surface on the first conductor layer 21 side is smaller than the area of the end surface on the second conductor layer 22 side.

When the first portion 31A has a tapered shape, the inclination angle of the tapered shape may be different stepwise. In this case, the inclination angle of the tapered shape may change in two stages, may change in three stages, or may change in four or more stages.

As described above, as illustrated in FIG. 2A, the first interlayer connection conductor 31 may have a tapered shape in which the area of the end surface on the first conductor layer 21 side is smaller than the area of the end surface on the second conductor layer 22 side.

Alternatively, the first interlayer connection conductor 31 may have a shape in which the area of the end surface on the first conductor layer 21 side is equal or substantially equal to the area of the end surface on the second conductor layer 22 side. That is, the first interlayer connection conductor 31 may not have a tapered shape.

Specifically, the first portion 31A may have a shape in which the area of the end surface on the first conductor layer 21 side is equal or substantially equal to the area of the end surface on the second conductor layer 22 side, and the second portion 31B may have a shape in which the area of the end surface on the first conductor layer 21 side is equal or substantially equal to the area of the end surface on the second conductor layer 22 side.

When the first interlayer connection conductor 31 has a tapered shape as illustrated in FIG. 2A, strain stress tends to concentrate on a necking portion (in particular, the necking portion between the first interlayer connection conductor 31 and the first conductor layer 21) of the first interlayer connection conductor 31. In contrast, when the first interlayer connection conductor 31 does not have a tapered shape, concentration of the strain stress on the necking portion of the first interlayer connection conductor 31 is eliminated. Therefore, the stress applied to the first interlayer connection conductor 31 is dispersed, so that the connection reliability is improved.

In the example illustrated in FIG. 2A, the end surface of the first portion 31A on the second conductor layer 22 side is flat. However, as described later, the end surface may protrude toward the second conductor layer 22 or may be recessed toward the first conductor layer 21.

The shape of the second interlayer connection conductor 32 is not limited to FIG. 2B.

The fourth portion 32B may have a tapered shape in which the area of the end surface on the third conductor layer 23 side is smaller than the area of the end surface on the fourth conductor layer 24 side. The connection strength between the fourth portion 32B and the fourth conductor layer 24 can be increased by increasing the area of the fourth portion 32B at the portion connected to the fourth conductor layer 24.

When the fourth portion 32B has a tapered shape, the inclination angle of the tapered shape may be different stepwise. In this case, the connection strength between the fourth portion 32B and the fourth conductor layer 24 can be further increased. The inclination angle of the tapered shape may change in two stages, may change in three stages, or may change in four or more stages.

Furthermore, the third portion 32A may have a tapered shape in which the area of the end surface on the third conductor layer 23 side is smaller than the area of the end surface on the fourth conductor layer 24 side.

When the third portion 32A has a tapered shape, the inclination angle of the tapered shape may be different stepwise. In this case, the inclination angle of the tapered shape may change in two stages, may change in three stages, or may change in four or more stages.

As described above, as illustrated in FIG. 2B, the second interlayer connection conductor 32 may have a tapered shape in which the area of the end surface on the third conductor layer 23 side is smaller than the area of the end surface on the fourth conductor layer 24 side.

Alternatively, the second interlayer connection conductor 32 may have a shape in which the area of the end surface on the third conductor layer 23 side is equal or substantially equal to the area of the end surface on the fourth conductor layer 24 side. That is, the second interlayer connection conductor 32 may not have a tapered shape.

Specifically, the third portion 32A may have a shape in which the area of the end surface on the third conductor layer 23 side is equal or substantially equal to the area of the end surface on the fourth conductor layer 24 side, and the fourth portion 32B may have a shape in which the area of the end surface on the third conductor layer 23 side is equal or substantially equal to the area of the end surface on the fourth conductor layer 24 side.

In the example illustrated in FIG. 2B, the end surface of the third portion 32A on the fourth conductor layer 24 side is flat. However, similarly to the first interlayer connection conductor 31, the end surface may protrude toward the fourth conductor layer 24 or may be recessed toward the third conductor layer 23.

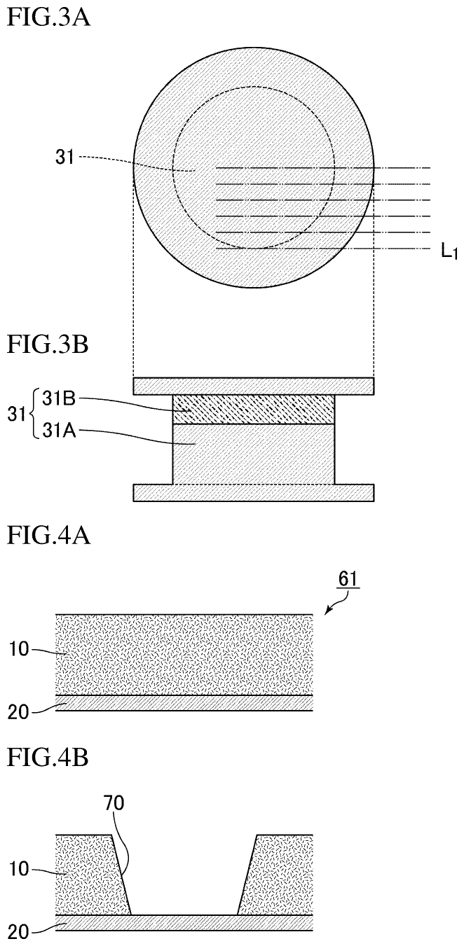

FIGS. 3A and 3B are schematic views for explaining an example of a method of measuring a height of a first interlayer connection conductor, a height of a first portion, and a height of a second portion.

As illustrated in FIG. 3A, cross-section polishing is performed in a slice shape at an interval of, for example, about 5 μm from the front (position indicated by Li in FIG. 3A) of the first interlayer connection conductor 31 to be measured. The polishing is advanced in the depth direction while the conductor is ground at regular intervals with coarse polishing paper, and if the following states (1) and (2) can be confirmed, finish polishing is performed using fine polishing paper.
(1) The distance of the interface between the conductor layer such as Cu foil, for example, and the first portion 31A such as a plated via, for example.
(2) The distance from the interface to a peak (highest point) of the first portion 31A.

A cross section in which these distances are at their maximum is to be obtained. The height T₁ of the first interlayer connection conductor 31, the height A₁ of the first portion 31A, and the height B₁ of the second portion 31B are measured from the obtained cross section.

The height T₂ of the second interlayer connection conductor 32, the height A₂ of the third portion 32A, and the height B₂ of the fourth portion 32B can also be obtained and measured in the same manner.

The circuit board 1A is produced, for example, by the following method. The circuit board 1A may be manufactured in a state of one chip (individual piece), or may be manufactured by manufacturing a collective board and then separating the collective board into individual pieces. The collective board here refers to a board including a plurality of circuit boards 1A.

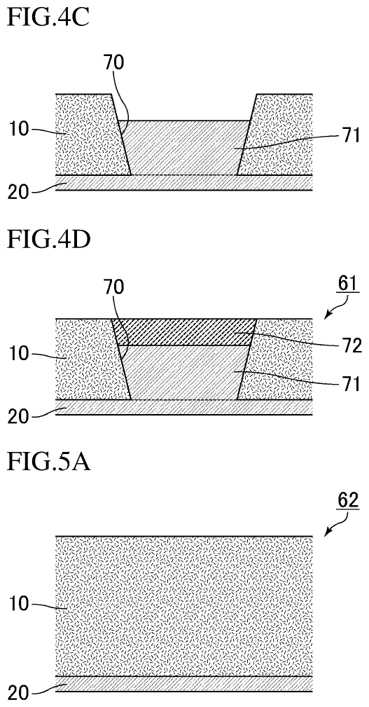

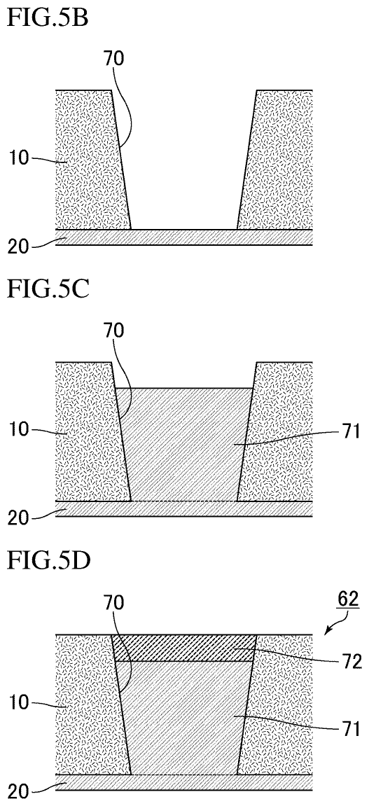

FIGS. 4A to 4D are cross-sectional views schematically illustrating an example of a step of preparing a first base filled with a first material and a second material.

First, as shown in FIG. 4A, a first base 61 in which the conductor layer 20 is formed on one main surface of the insulating layer 10 is prepared.

For example, a metal foil such as a Cu foil is laminated on one main surface of the insulating layer 10, and the metal foil is patterned by photolithography to form the conductor layer 20. The insulating layer 10 is, for example, a resin sheet including a thermoplastic resin such as a liquid crystal polymer as a main component.

Next, as illustrated in FIG. 4B, a via hole 70 penetrating the insulating layer 10 and exposing a portion of the upper surface of the conductor layer 20 is formed in the first base 61. The via hole 70 preferably has a tapered shape in which the hole diameter decreases toward the conductor layer 20.

For example, the via hole 70 is formed in the insulating layer 10 with a laser, for example, such that the upper surface of the conductor layer 20 is exposed.

Subsequently, as illustrated in FIG. 4C, the via hole 70 is filled with a first material 71. The via hole 70 is partially filled with the first material 71. The height of the first material 71 is not limited as long as it does not exceed the thickness of the insulating layer 10.

For example, the via hole 70 is filled with a plating metal such as Cu as the first material 71 by a plating process such as an electrolytic plating process. The first portion 31A (see FIG. 7) is formed of the first material 71.

Thereafter, as illustrated in FIG. 4D, a second material 72 is poured into the via hole 70, which has been filled with the first material 71. The space in the via hole 70 is filled with the first material 71 and the second material 72.

For example, the via hole 70 after being filled with the first material 71 is filled with a conductive paste including a metal material such as Cu or Sn and a resin material as the second material 72. The second material 72 is solidified by, for example, the heating press described later to form the second portion 31B (see FIG. 7).

Although a plating metal such as Sn, for example, can be used as the second material 72, depending on the metal selected as the second material 72, there is a risk that the first material 71 defining and functioning as the underlying layer will remelt. Therefore, from the viewpoint of improving the degree of freedom of selection of the first material 71 and the second material 72, preferably, the via hole 70 is filled with the plating metal as the first material 71, and then with the conductive paste as the second material 72.

FIGS. 5A to 5D are cross-sectional views schematically illustrating an example of a step of preparing a second base filled with a first material and a second material. The method illustrated in FIGS. 5A to 5D is the same as or similar to the method illustrated in FIGS. 4A to 4D.

First, as illustrated in FIG. 5A, a second base 62 in which the conductor layer 20 is formed on one main surface of the insulating layer 10 is prepared.

For example, a metal foil such as a Cu foil is laminated on one main surface of the insulating layer 10, and the metal foil is patterned by photolithography to form the conductor layer 20. The insulating layer 10 is, for example, a resin sheet including a thermoplastic resin such as a liquid crystal polymer as a main component.

Next, as illustrated in FIG. 5B, the via hole 70 penetrating the insulating layer 10 and exposing a portion of the upper surface of the conductor layer 20 is formed in the second base 62. The via hole 70 preferably has a tapered shape in which the hole diameter decreases toward the conductor layer 20.

For example, the via hole 70 is formed in the insulating layer 10 with a laser, for example, such that the upper surface of the conductor layer 20 is exposed.

Subsequently, as illustrated in FIG. 5C, the via hole 70 is filled with the first material 71. The via hole 70 is partially filled with the first material 71. The height of the first material 71 is not limited as long as it does not exceed the thickness of the insulating layer 10.

For example, the via hole 70 is filled with a plating metal such as Cu as the first material 71 by a plating process such as an electrolytic plating process. The third portion 32A (see FIG. 7) is formed of the first material 71.

Thereafter, as illustrated in FIG. 5D, the second material 72 is poured into the via hole 70, which has been filled with the first material 71. The space in the via hole 70 is filled with the first material 71 and the second material 72.

For example, the via hole 70 after being filled with the first material 71 is filled with a conductive paste including a metal material such as Cu or Sn and a resin material as the second material 72. The second material 72 is solidified by the heating press described later to form the fourth portion 32B (see FIG. 7).

Although a plating metal such as Sn, for example, can be used as the second material 72, depending on the metal selected as the second material 72, there is a risk that the first material 71 defining and functioning as the underlying layer will remelt. Therefore, from the viewpoint of improving the degree of freedom of selection of the first material 71 and the second material 72, preferably, the via hole 70 is filled with the plating metal as the first material 71, and then with the conductive paste as the second material 72.

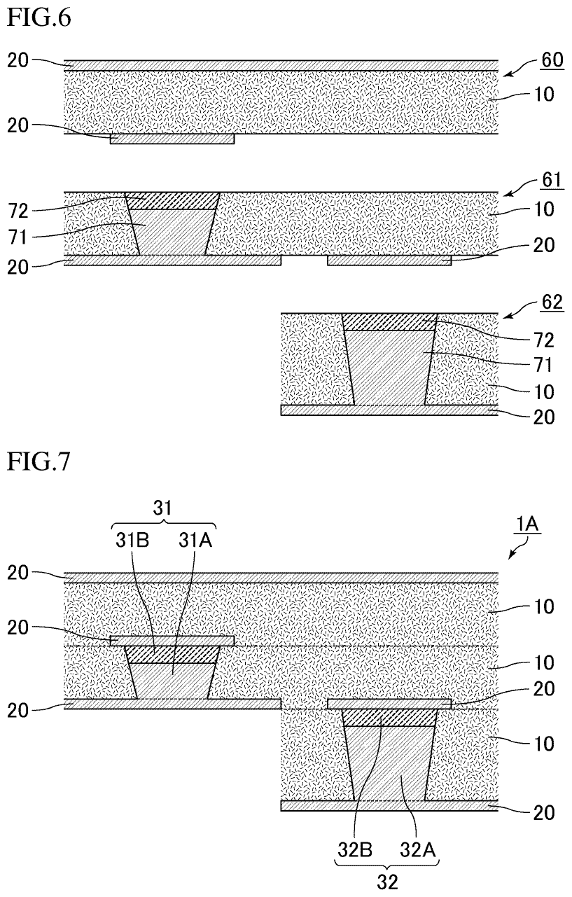

FIG. 6 is a cross-sectional view schematically illustrating an example of a step of stacking bases.

As illustrated in FIG. 6, a plurality of bases including the first base 61 and the second base 62 are stacked. FIG. 6 illustrates an example in which the base 60 not filled with the first material 71 and the second material 72, the first base 61 filled with the first material 71 and the second material 72, and the second base 62 filled with the first material 71 and the second material 72 are stacked, but the present invention is not limited as long as the first interlayer connection conductor 31 and the second interlayer connection conductor 32 illustrated in FIG. 7 are formed.

FIG. 7 is a cross-sectional view schematically illustrating an example of a step of collectively pressing.

As illustrated in FIG. 7, heat and pressure are applied to press them at once. As a result, the circuit board 1A is produced.

According to this example of a producing method, the circuit board 1A can be easily manufactured by collectively pressing the insulating layers 10. Therefore, the complexity of the manufacturing process of the circuit board 1A is reduced, and the manufacturing cost is low.

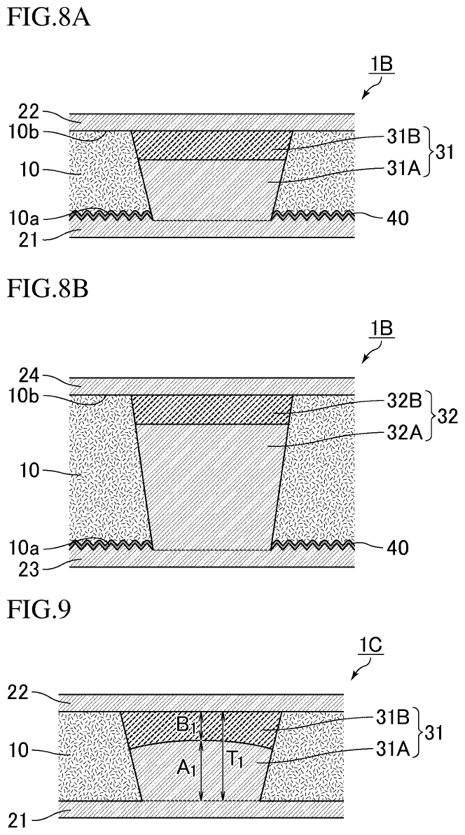

Although not illustrated in, for example, FIG. 2A, at least the interface between the first conductor layer 21 and the insulating layer 10 may be provided with a rustproof layer 40 (see FIG. 8A) to be described later. Similarly, although not illustrated in, for example, FIG. 2B, at least the interface between the third conductor layer 23 and the insulating layer 10 may be provided with the rustproof layer 40 (see FIG. 8B) to be described later. The same applies to the following example embodiments.

The rustproof layer 40 is formed by, for example, subjecting the surface of the metal foil to a rustproof treatment using a metal such as Zn, Ni, Cr, Mo, or Pt.

When the circuit board 1A is produced by collective pressing described above, the rustproof layer 40 is provided at the interface between the first conductor layer 21 or the third conductor layer 23 and the insulating layer 10 to prevent oxidation of the metal foil such as the Cu foil, for example, of the first conductor layer 21 or the third conductor layer 23, so that it is possible to reduce or prevent a decrease in adhesion between the first conductor layer 21 or the third conductor layer 23 and the insulating layer 10.

When the circuit board 1A is manufactured by collective pressing, the thermal load applied to the interface between the first conductor layer 21 or the third conductor layer 23 and the insulating layer 10 is greater than the interface between the second conductor layer 22 or the fourth conductor layer 24 and the insulating layer 10. Therefore, preferably, the rustproof layer 40 is provided at least at the interface between the first conductor layer 21 or the third conductor layer 23 and the insulating layer 10.

In a case where the rustproof layer 40 is provided at the interface between the first conductor layer 21 and the insulating layer 10, the rustproof layer 40 may be in contact with the first portion 31A, or may not be in contact with the first portion 31A. Similarly, in a case where the rustproof layer 40 is provided at the interface between the third conductor layer 23 and the insulating layer 10, the rustproof layer 40 may be in contact with the third portion 32A, or may not be in contact with the third portion 32A.

The rustproof layer 40 is preferably not provided between the first portion 31A and the first conductor layer 21. Similarly, the rustproof layer 40 is preferably not provided between the third portion 32A and the third conductor layer 23.

The rustproof layer 40 is preferably not provided at the interface between the second conductor layer 22 and the insulating layer 10. Similarly, the rustproof layer 40 is preferably not provided at the interface between the fourth conductor layer 24 and the insulating layer 10.

The rustproof layer 40 is preferably not provided between the second portion 31B and the second conductor layer 22. Similarly, the rustproof layer 40 is preferably not provided between the fourth portion 32B and the fourth conductor layer 24.

FIG. 8A is a cross-sectional view schematically illustrating an example of a circuit board according to a second example embodiment of the present invention. FIG. 8B is a cross-sectional view schematically illustrating an example of the circuit board at a position different from that in FIG. 8A.

In a circuit board 1B illustrated in FIG. 8A, the surface roughness of the portion of a first conductor layer 21 in contact with an insulating layer 10 is greater than the surface roughness of the portion of a second conductor layer 22 in contact with the insulating layer 10. Furthermore, as illustrated in FIG. 8B, the surface roughness of the portion of a third conductor layer 23 in contact with the insulating layer 10 is greater than the surface roughness of the portion of a fourth conductor layer 24 in contact with the insulating layer 10.

As illustrated in FIGS. 8A and 8B, by increasing the surface roughness of the first conductor layer 21 or the third conductor layer 23 at the portion in contact with the insulating layer 10, the adhesion area between the insulating layer 10 and the first conductor layer 21 or the third conductor layer 23 increases, so that the adhesion strength between the two can be increased. Therefore, when, for example, an electronic component is mounted on the first conductor layer 21 or the third conductor layer 23, the electronic component is hardly peeled off.

When the surface roughness of the first conductor layer 21 in contact with the insulating layer 10 is greater than the surface roughness of the second conductor layer 22 in contact with the insulating layer 10, the surface roughness of the third conductor layer 23 in contact with the insulating layer 10 may be smaller than the surface roughness of the fourth conductor layer 24 in contact with the insulating layer 10, or may be equal or substantially equal to the surface roughness of the fourth conductor layer 24 in contact with the insulating layer 10.

Further, when the surface roughness of the third conductor layer 23 in contact with the insulating layer 10 is greater than the surface roughness of the fourth conductor layer 24 in contact with the insulating layer 10, the surface roughness of the first conductor layer 21 in contact with the insulating layer 10 may be smaller than the surface roughness of the second conductor layer 22 in contact with the insulating layer 10, or may be equal or substantially equal to the surface roughness of the second conductor layer 22 in contact with the insulating layer 10.

In the example illustrated in FIG. 8A, a rustproof layer 40 is provided at the interface between the first conductor layer 21 and the insulating layer 10, but the rustproof layer 40 may not be provided at the interface between the first conductor layer 21 and the insulating layer 10.

In the example illustrated in FIG. 8B, the rustproof layer 40 is provided at the interface between the third conductor layer 23 and the insulating layer 10, but the rustproof layer 40 may not be provided at the interface between the third conductor layer 23 and the insulating layer 10.

FIG. 9 is a cross-sectional view schematically illustrating an example of a circuit board according to a third example embodiment of the present invention.

In a circuit board 1C illustrated in FIG. 9, the end surface of a first portion 31A on a second conductor layer 22 side protrudes toward the second conductor layer 22. In the example illustrated in FIG. 9, the end surface of the first portion 31A on the second conductor layer 22 side protrudes symmetrically.

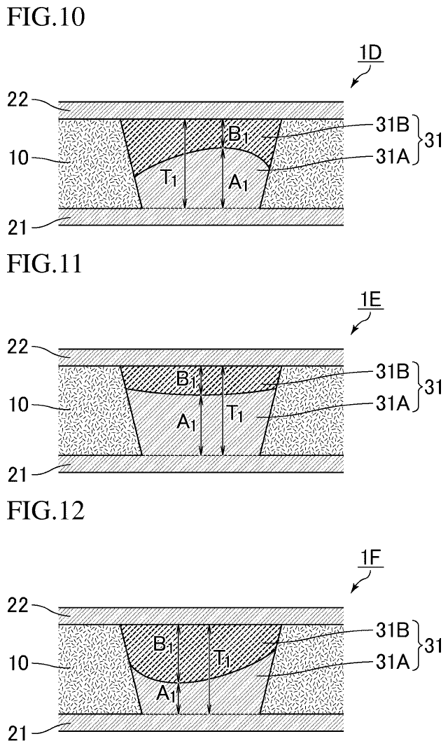

FIG. 10: is a cross-sectional view schematically illustrating another example of a circuit board according to a fourth example embodiment of the present invention.

In a circuit board 1D illustrated in FIG. 10, similarly to FIG. 9, the end surface of a first portion 31A on a second conductor layer 22 side protrudes toward a second conductor layer 22. On the other hand, in the example illustrated in FIG. 10, the end surface of the first portion 31A on the second conductor layer 22 side protrudes asymmetrically.

As illustrated in FIG. 9 or 10, when the end surface of the first portion 31A on the second conductor layer 22 side protrudes toward the second conductor layer 22, the connection area between the first portion 31A and a second portion 31B increases, so that the connection strength between the first portion 31A and the second portion 31B can be increased.

The height A₁ of the first portion 31A may be equal or substantially equal to the height B₁ of the second portion 31B, and may be lower than the height B₁ of the second portion 31B (A₁<B₁), but is preferably higher than the height B₁ of the second portion 31B (A₁>B₁). The height A₁ of the first portion 31A is defined as the height of the highest portion, and the height B₁ of the second portion 31B is defined as the height of the lowest portion.

In the examples illustrated in FIGS. 9 and 10, there is one peak, but there may be two or more peaks. When there are two or more peaks, their sizes, heights, and shapes, for example, may be the same or different.

Although not illustrated, similarly in a second interlayer connection conductor 32, the end surface of a third portion 32A on a fourth conductor layer 24 side may protrude toward the fourth conductor layer 24. In this case, the end surface of the third portion 32A on the fourth conductor layer 24 side may protrude symmetrically, and may protrude asymmetrically.

When the end surface of the third portion 32A on the fourth conductor layer 24 side protrudes toward the fourth conductor layer 24, the height A₂ of the third portion 32A may be equal or substantially equal to the height B₂ of the fourth portion 32B, and may be lower than the height B₂ of the fourth portion 32B (A₂<B₂), but is preferably higher than the height B₂ of the fourth portion 32B (A₂>B₂). Note that the height A₂ of the third portion 32A is defined as the height of the highest portion, and the height B₂ of the fourth portion 32B is defined as the height of the lowest portion.

FIG. 11 is a cross-sectional view schematically illustrating an example of a circuit board according to a fifth example embodiment of the present invention.

In a circuit board 1E illustrated in FIG. 11, the end surface of a first portion 31A on a second conductor layer 22 side is recessed toward a first conductor layer 21. In the example illustrated in FIG. 11, the end surface of the first portion 31A on the second conductor layer 22 side is symmetrically recessed.

FIG. 12 is a cross-sectional view schematically illustrating another example of a circuit board according to the fifth example embodiment of the present invention.

In a circuit board 1F illustrated in FIG. 12, similarly to FIG. 11, the end surface of the first portion 31A on the second conductor layer 22 side is recessed toward the first conductor layer 21. On the other hand, in the example illustrated in FIG. 12, the end surface of the first portion 31A on the second conductor layer 22 side is asymmetrically recessed.

As illustrated in FIG. 11 or 12, when the end surface of the first portion 31A on the second conductor layer 22 side is recessed toward the first conductor layer 21, the connection area between the first portion 31A and a second portion 31B increases, so that the connection strength between the first portion 31A and the second portion 31B can be increased.

The height A₁ of the first portion 31A may be equal or substantially equal to the height B₁ of the second portion 31B, and may be lower than the height B₁ of the second portion 31B (A₁<B₁), but is preferably higher than the height B₁ of the second portion 31B (A₁>B₁). The height A₁ of the first portion 31A is defined as the height of the lowest portion, and the height B₁ of the second portion 31B is defined as the height of the highest portion.

In the examples illustrated in FIGS. 11 and 12, there is one peak of the valley, but there may be two or more peaks of the valley. When there are two or more peaks of the valley, their sizes, depths, and shapes, for example, may be the same or different.

A portion protruding toward the second conductor layer 22 and a portion recessed toward the first conductor layer 21 may be mixed on the end surface of the first portion 31A on the second conductor layer 22 side.

Although not illustrated, similarly in a second interlayer connection conductor 32, the end surface of the third portion 32A on a fourth conductor layer 24 side may be recessed toward the third conductor layer 23. In this case, the end surface of the third portion 32A on the fourth conductor layer 24 side may be recessed symmetrically, and may be recessed asymmetrically.

When the end surface of the third portion 32A on the fourth conductor layer 24 side is recessed toward the third conductor layer 23, the height A₂ of the third portion 32A may be equal or substantially equal to the height B₂ of the fourth portion 32B, and may be lower than the height B₂ of the fourth portion 32B (A₂<B₂), but is preferably higher than the height B₂ of the fourth portion 32B (A₂>B₂). The height A₂ of the third portion 32A is defined as the height of the lowest portion, and the height B₂ of the fourth portion 32B is defined as the height of the highest portion.

A portion protruding toward the fourth conductor layer 24 and a portion recessed toward the third conductor layer 23 may be mixed on the end surface of the third portion 32A on the fourth conductor layer 24 side.

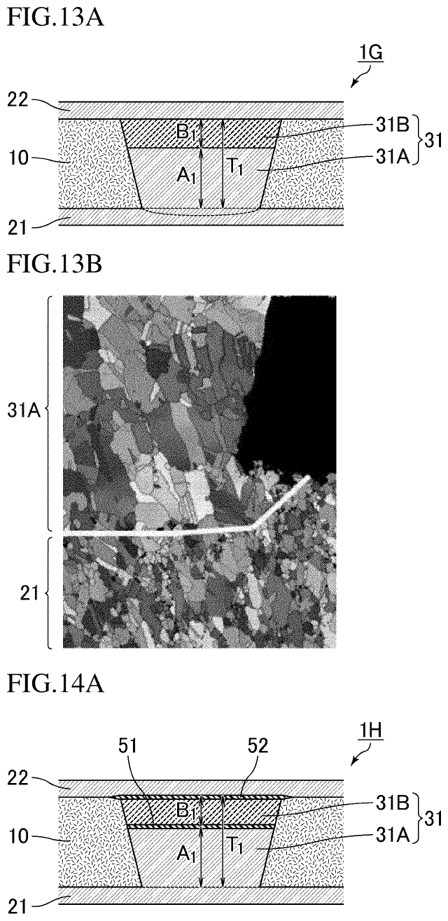

FIG. 13A is a cross-sectional view schematically illustrating an example of a circuit board according to a sixth example embodiment of the present invention.

In a circuit board 1G illustrated in FIG. 13A, the end surface of a first portion 31A on a first conductor layer 21 side protrudes to a first conductor layer 21 side from the interface between the first conductor layer 21 and an insulating layer 10.

As illustrated in FIG. 13A, when the end surface of the first portion 31A on the first conductor layer 21 side protrudes to the first conductor layer 21 side from the interface between the first conductor layer 21 and the insulating layer 10, the connection area between the first portion 31A and the first conductor layer 21 increases, so that the connection strength between the first portion 31A and the first conductor layer 21 can be increased.

In the example illustrated in FIG. 13A, the end surface of the first portion 31A on the first conductor layer 21 side protrudes symmetrically, but may protrude asymmetrically.

In the example illustrated in FIG. 13A, there is one peak, but there may be two or more peaks. When there are two or more peaks, their sizes, heights, and shapes, for example, may be the same or different.

FIG. 13B is an example of an EBSD photograph showing an enlarged view of a circuit board according to the sixth example embodiment of the present invention.

The protrusion of the end face of the first portion 31A on the side of the first conductor layer 21 can be determined from the difference in the size of crystal grains, for example, by irradiating electron beams using a method such as electron backscatter diffraction (EBSD) as shown in FIG. 13B.

Although not illustrated, similarly in a second interlayer connection conductor 32, the end surface of the third portion 32A on the third conductor layer 23 side may protrude to the third conductor layer 23 side from the interface between the third conductor layer 23 and the insulating layer 10. In this case, the end surface of the third portion 32A on the third conductor layer 23 side may protrude symmetrically, and may protrude asymmetrically.

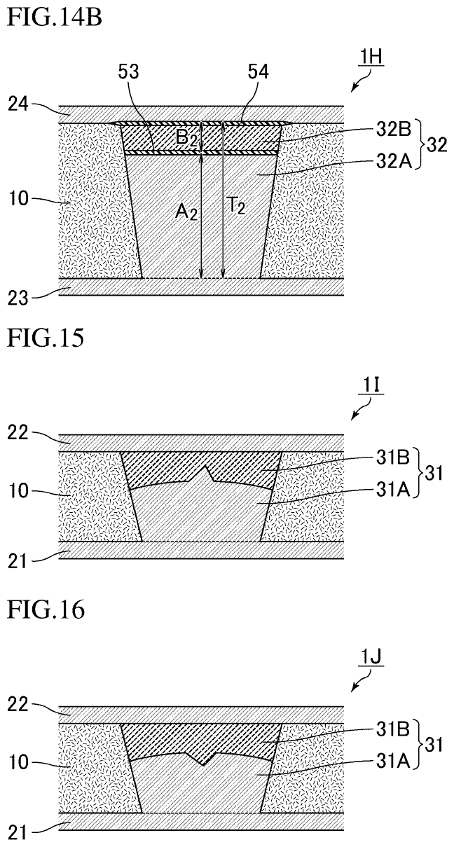

FIG. 14A is a cross-sectional view schematically illustrating an example of a circuit board according to a seventh example embodiment of the present invention. FIG. 14B is a cross-sectional view schematically illustrating an example of the circuit board at a position different from that in FIG. 14A.

In a circuit board 1H illustrated in FIG. 14A, a first portion 31A is bonded to a second portion 31B with a first intermediate layer 51 interposed therebetween, the first intermediate layer 51 including a metal included in the first portion 31A and a metal included in the second portion 31B, and bonded to a first conductor layer 21 without the first intermediate layer 51 interposed therebetween.

As an example, in the second portion 31B, the first intermediate layer 51 including Cu and Sn is provided at the end portion on the first portion 31A side. In this case, for example, the first intermediate layer 51 is made of a Cu—Sn alloy such as Cu₃Sn or Cu₅Sn. However, the composition of the first intermediate layer 51 is different from the composition of the second portion 31B.

The second portion 31B is bonded to the second conductor layer 22 with a second intermediate layer 52 interposed therebetween, the second intermediate layer 52 including a metal included in the second portion 31B and a metal included in the second conductor layer 22.

As an example, in the second portion 31B, the second intermediate layer 52 including Cu and Sn is provided at the end portion on the second conductor layer 22 side. In this case, for example, the second intermediate layer 52 is made of a Cu—Sn alloy such as Cu₃Sn or Cu₅Sn. However, the composition of the second intermediate layer 52 is different from the composition of the second portion 31B.

The first intermediate layer 51 may or may not extend to the interface between the first portion 31A and the insulating layer 10. When the first intermediate layer 51 extends to the interface between the first portion 31A and the insulating layer 10, the first intermediate layer 51 may extend to the interface between the first conductor layer 21 and the insulating layer 10. Accordingly, the connection strength between the first portion 31A and the first conductor layer 21 can be further increased.

The second intermediate layer 52 may or may not extend to the interface between the second conductor layer 22 and the insulating layer 10.

The first intermediate layer 51 may include one layer or two or more layers. Similarly, the second intermediate layer 52 may include one layer or two or more layers.

The first intermediate layer 51 and the second intermediate layer 52 can be confirmed, for example, by observing a cross section of the insulating layer 10 cut in a direction parallel or substantially parallel to the thickness direction using a scanning electron microscope (SEM). Since the first intermediate layer 51 and the second intermediate layer 52 are different in composition from both the first portion 31A and the second portion 31B, it is displayed in a color tone different from those of the first portion 31A and the second portion 31B in the SEM photograph.

Even when the kinds of included metal elements are the same, the case where the content ratios of the respective metal elements are different is also considered as being “different in composition”. For example, it can be said that the compositions of Cu₅Sn, Cu₃Sn, Cu₆Sn₅, or the like are all compositions including Cu and Sn as metal species, but the compositions are different from each other because the content ratios of the metal species are different.

In a circuit board 1H illustrated in FIG. 14B, a third portion 32A is bonded to a fourth portion 32B with a third intermediate layer 53 interposed therebetween, the third intermediate layer 53 including a metal included in the third portion 32A and a metal included in a fourth portion 32B, and bonded to a third conductor layer 23 without the third intermediate layer 53 interposed therebetween.

As an example, in the fourth portion 32B, the third intermediate layer 53 including Cu and Sn is provided at the end portion on the third portion 32A side. In this case, for example, the third intermediate layer 53 is made of a Cu—Sn alloy such as Cu₃Sn or Cu₅Sn. However, the composition of the third intermediate layer 53 is different from the composition of the fourth portion 32B.

The fourth portion 32B is bonded to the fourth conductor layer 24 with a fourth intermediate layer 54 interposed therebetween, the fourth intermediate layer 54 including a metal included in the fourth portion 32B and a metal included in the fourth conductor layer 24.

As an example, in the fourth portion 32B, the fourth intermediate layer 54 including Cu and Sn is provided at the end portion on the fourth conductor layer 24 side. In this case, for example, the fourth intermediate layer 54 is made of a Cu—Sn alloy such as Cu₃Sn or Cu₅Sn. However, the composition of the fourth intermediate layer 54 is different from the composition of the fourth portion 32B.

The third intermediate layer 53 may or may not extend to the interface between the third portion 32A and the insulating layer 10. When the third intermediate layer 53 extends to the interface between the third portion 32A and the insulating layer 10, the third intermediate layer 53 may extend to the interface between the third conductor layer 23 and the insulating layer 10. Accordingly, the connection strength between the third portion 32A and the third conductor layer 23 can be further increased.

The fourth intermediate layer 54 may or may not extend to the interface between the fourth conductor layer 24 and the insulating layer 10.

The third intermediate layer 53 may include one layer or two or more layers. Similarly, the fourth intermediate layer 54 may include one layer or two or more layers.

FIG. 15 is a cross-sectional view schematically illustrating an example of a circuit board according to an eighth example embodiment of the present invention.

In a circuit board 1I illustrated in FIG. 15, a portion protruding toward a second conductor layer 22 exists in a portion of the end surface of a first portion 31A on a second conductor layer 22 side.

As illustrated in FIG. 15, when there is a portion (hereinafter, also referred to as a protruding portion) protruding from a portion of the end surface of the first portion 31A on the second conductor layer 22 side, the connection area between the first portion 31A and a second portion 31B increases as in FIG. 9 or 10, so that the connection strength between the first portion 31A and the second portion 31B can be increased.

One protruding portion may exist or two or more protruding portions may exist in a portion of the end surface of the first portion 31A on the second conductor layer 22 side. When there are two or more protruding portions, their sizes, heights, and shapes, for example, may be the same or different.

The height of the protruding portion is, for example, about 1 μm or more and about 20 μm or less. The shape of the protruding portion is not limited to the shape illustrated in FIG. 15.

The maximum diameter of the protruding portion is, for example, about 1 μm or more and about 10 μm or less. Here, the maximum diameter of the protruding portion refers to a diameter when the cross-sectional shape is circular or substantially circular, and refers to a maximum length passing through the center of the cross-section when the cross-sectional shape is other than circular.

Although not illustrated, similarly in a second interlayer connection conductor 32, a portion of the end surface of a third portion 32A on a fourth conductor layer 24 side may include a portion protruding toward the fourth conductor layer 24.

FIG. 16 is a cross-sectional view schematically illustrating an example of a circuit board according to a ninth example embodiment of the present invention.

In a circuit board 1J illustrated in FIG. 16, a portion recessed toward a first conductor layer 21 exists in a portion of the end surface of a first portion 31A on a second conductor layer 22 side.

As illustrated in FIG. 16, when there is a portion (hereinafter, also referred to as a recessed portion) recessed from a portion of the end surface of the first portion 31A on the second conductor layer 22 side, the connection area between the first portion 31A and a second portion 31B increases as in FIG. 11 or 12, so that the connection strength between the first portion 31A and the second portion 31B can be increased.

One recessed portion may exist or two or more recessed portions may exist in a portion of the end surface of the first portion 31A on the second conductor layer 22 side. When there are two or more recessed portions, their sizes, depths, and shapes, for example, may be the same or different.

The depth of the recessed portion is, for example, about 1 μm or more and about 20 μm or less. The shape of the recessed portion is not limited to the shape illustrated in FIG. 16.

The maximum diameter of the recessed portion is, for example, about 1 μm or more and about 10 μm or less. Here, the maximum diameter of the recessed portion refers to a diameter when the cross-sectional shape is circular or substantially circular, and refers to a maximum length passing through the center of the cross-section when the cross-sectional shape is other than circular.

A protruding portion and a recessed portion may be mixed on a portion of the end surface of the first portion 31A on the second conductor layer 22 side.

Although not illustrated, similarly in a second interlayer connection conductor 32, a portion of the end surface of a third portion 32A on a fourth conductor layer 24 side may include a portion recessed toward a third conductor layer 23.

A protruding portion and a recessed portion may be mixed on a portion of the end surface of the third portion 32A on the fourth conductor layer 24 side.

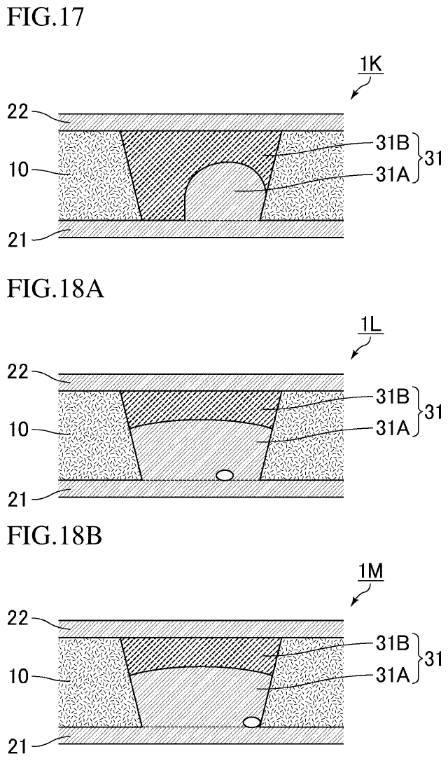

FIG. 17 is a cross-sectional view schematically illustrating another example of a circuit board according to the ninth example embodiment of the present invention.

As in a circuit board 1K illustrated in FIG. 17, a portion of the second portion 31B may be bonded to the first conductor layer 21.

Although not illustrated, similarly in the second interlayer connection conductor 32, a portion of the fourth portion 32B may be bonded to the third conductor layer 23.

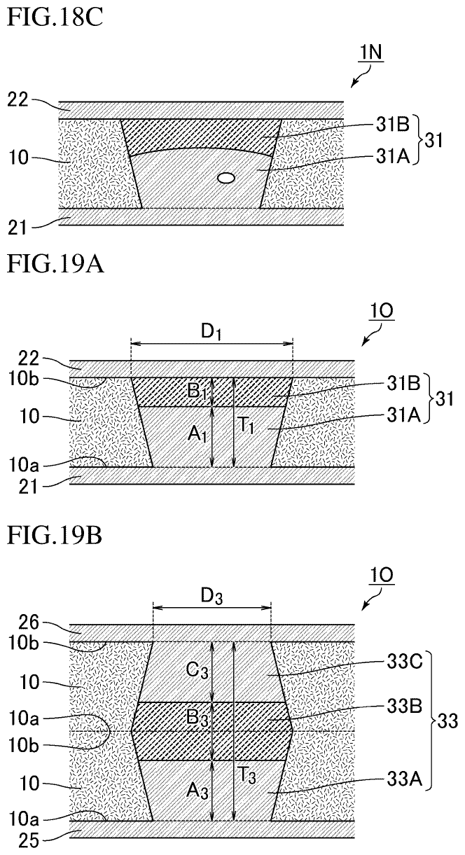

FIGS. 18A, 18B, and 18C are cross-sectional views schematically illustrating an example of a circuit board according to a tenth example embodiment of the present invention.

As in a circuit board 1L illustrated in FIG. 18A, a circuit board 1M illustrated in FIG. 18B, or a circuit board 1N illustrated in FIG. 18C, there may be a void inside a first portion 31A. The number, size, and position, for example, of the voids are not limited. For example, the void may exist in the vicinity of the interface between the first portion 31A and a first conductor layer 21 as illustrated in FIG. 18A, may exist in the vicinity of the interface between an insulating layer 10 and the first conductor layer 21 as illustrated in FIG. 18B, or may exist in the vicinity of the interface between the first portion 31A and a second portion 31B as illustrated in FIG. 18C. In addition to the void or instead of the void, a residue of a resin (carbide) or an oxide of a copper foil (copper oxide) may be present, for example.

Although not illustrated, similarly in a second interlayer connection conductor 32, there may be a void inside a third portion 32A. The number, size, and position, for example, of the voids are not limited. In addition to the void or instead of the void, a residue of a resin (carbide) or an oxide of a copper foil (copper oxide) may be present, for example.

FIG. 19A is a cross-sectional view schematically illustrating an example of a circuit board according to an eleventh example embodiment of the present invention. FIG. 19B is a cross-sectional view schematically illustrating an example of the circuit board at a position different from that in FIG. 19A.

Although the overall configuration is not illustrated in FIGS. 19A and 19B, a circuit board 10 includes an insulating layer 10, a first conductor layer 21, a second conductor layer 22, a fifth conductor layer 25, a sixth conductor layer 26, a first interlayer connection conductor 31, and a third interlayer connection conductor 33.

Although not illustrated, the circuit board 10 may or may not include a second interlayer connection conductor 32.

The fifth conductor layer 25 is provided on a first main surface 10a of the insulating layer 10 and is connected to the third interlayer connection conductor 33.

The sixth conductor layer 26 is provided on a second main surface 10b of the insulating layer 10 and is connected to the third interlayer connection conductor 33.

Each of the fifth conductor layer 25 and the sixth conductor layer 26 may have a patterned shape obtained by patterning the layer into lines, for example, or may have a planar shape spread over one surface. The shapes of the fifth conductor layer 25 and the sixth conductor layer 26 may be the same or substantially the same as or different from each other.

Each of the fifth conductor layer 25 and the sixth conductor layer 26 is, for example, a metal layer including at least one of copper, silver, aluminum, stainless steel, nickel, gold, or these metals. The materials of the fifth conductor layer 25 and the sixth conductor layer 26 may be the same as or different from each other. Each of the fifth conductor layer 25 and the sixth conductor layer 26 is, for example, preferably made of a metal foil, and more preferably made of a copper (Cu) foil.

Each of the fifth conductor layer 25 and the sixth conductor layer 26 may have a mat surface on one main surface and a shiny surface on the other main surface.

The thickness (length in the stacking direction) of each of the fifth conductor layer 25 and the sixth conductor layer 26 is, for example, preferably about 1 μm or more and about 35 μm or less, and more preferably about 6 μm or more and about 18 μm or less. The thickness of the fifth conductor layer 25 and the sixth conductor layer 26 may be the same or substantially the same as or different from each other.

The fifth conductor layer 25 and the sixth conductor layer 26 may or may not be parallel or substantially parallel to each other.

One insulating layer 10 may be provided between the fifth conductor layer 25 and the sixth conductor layer 26, or two or more insulating layers 10 may be provided between them. When two or more insulating layers 10 are provided between the fifth conductor layer 25 and the sixth conductor layer 26, the configurations of the insulating layers 10 may be the same or substantially the same as or different from each other. In addition, when two or more insulating layers 10 are provided between the fifth conductor layer 25 and the sixth conductor layer 26, the thickness of the insulating layers 10 may be the same or substantially the same as or different from each other.

The third interlayer connection conductor 33 penetrates the insulating layer 10 in the thickness direction.

The third interlayer connection conductor 33 is connected to the fifth conductor layer 25 and the sixth conductor layer 26 while penetrating the insulating layer 10 in the thickness direction but not penetrating the fifth conductor layer 25 and the sixth conductor layer 26. Therefore, the third interlayer connection conductor 33 penetrates the insulating layer(s) 10 in the thickness direction by the number of layers provided between the fifth conductor layer 25 and the sixth conductor layer 26. For example, the third interlayer connection conductor 33 penetrates two insulating layers 10 in the thickness direction.

The insulating layer 10 provided with the third interlayer connection conductor 33 may be the same layer as or different from the insulating layer 10 provided with the first interlayer connection conductor 31, but is preferably a different layer. In this case, the thickness of the insulating layer 10 provided with the third interlayer connection conductor 33 may be greater than the thickness of the insulating layer 10 provided with the first interlayer connection conductor 31, may be smaller than the thickness of the insulating layer 10 provided with the first interlayer connection conductor 31, or may be equal or substantially equal to the thickness of the insulating layer 10 provided with the first interlayer connection conductor 31.

For example, when the circuit board 10 is a multilayer circuit board including a plurality of insulating layers 10, the insulating layer 10 provided with the third interlayer connection conductor 33 is preferably a layer different from the insulating layer 10 provided with the first interlayer connection conductor 31 in the thickness direction. In this case, the insulating layer 10 provided with the third interlayer connection conductor 33 and the insulating layer 10 provided with the first interlayer connection conductor 31 may be adjacent to each other in the thickness direction, and at least one insulating layer 10 may be provided between the insulating layer 10 provided with the third interlayer connection conductor 33 and the insulating layer 10 provided with the first interlayer connection conductor 31.

In a cross section perpendicular or substantially perpendicular to the thickness direction, preferably the shape of the third interlayer connection conductor 33 is circular. In this case, not only a perfect circle but also an ellipse, an oval, and the like are included in the circle. The cross-sectional shapes of the first interlayer connection conductor 31 and the third interlayer connection conductor 33 may be the same or substantially the same as or different from each other.

The third interlayer connection conductor 33 includes a fifth portion 33A, a sixth portion 33B and a seventh portion 33C in the thickness direction.

The fifth portion 33A is, for example, a plated via.

When the fifth portion 33A is a plated via, the metal included in the fifth portion 33A is preferably the same as the metal of the fifth conductor layer 25, and is, for example, Cu. The metal included in the fifth portion 33A is preferably the same as the metal included in the first portion 31A.

The sixth portion 33B has lower conductivity than the fifth portion 33A.

The sixth portion 33B is, for example, a paste via. When the circuit board 10 is manufactured by collective pressing described later, the sixth portion 33B defines and functions as a bonding material, so that the fifth portion 33A and the sixth conductor layer 26 can be conductively connected.

When the sixth portion 33B is a paste via, examples of the metal included in the sixth portion 33B include Cu, Sn, Ag, Ni, Cr, Pt, Mo, Ga, Ge, Sb, In, Pb, or an alloy including at least one of these metals. The metal included in the sixth portion 33B may be the same as or different from the metal included in the fifth portion 33A. The metal included in the sixth portion 33B is, for example, an alloy including Cu and Sn. The metal included in the sixth portion 33B is preferably the same as the metal included in the second portion 31B.

Alternatively, the sixth portion 33B may be, for example, a plated via.

When the sixth portion 33B is a plated via, examples of the metal included in the sixth portion 33B include Sn. By using Sn having a low melting point, it is easy to cause the sixth portion 33B to define and function as a bonding material. The metal included in the sixth portion 33B is preferably the same as the metal included in the second portion 31B.

The seventh portion 33C has higher conductivity than the sixth portion 33B.

The seventh portion 33C is, for example, a plated via.

When the seventh portion 33C is a plated via, the metal included in the seventh portion 33C is preferably the same as the metal of the sixth conductor layer 26, and is, for example, Cu. The metal included in the seventh portion 33C is preferably the same as the metal included in the fifth portion 33A.

One end portion of the fifth portion 33A is bonded to the fifth conductor layer 25, and the other end portion of the fifth portion 33A is bonded to one end portion of the sixth portion 33B.

The fifth portion 33A and the fifth conductor layer 25 are directly bonded without interposing a dissimilar material therebetween. Therefore, at the interface between the fifth portion 33A and the fifth conductor layer 25, there is a portion where different materials do not exist, that is, a portion where the fifth portion 33A and the fifth conductor layer 25 are in direct contact with each other.

The other end portion of the sixth portion 33B is bonded to one end portion of the seventh portion 33C.

The other end portion of the seventh portion 33C is bonded to the sixth conductor layer 26.

The seventh portion 33C and the sixth conductor layer 26 are directly bonded without interposing a dissimilar material therebetween. Therefore, at the interface between the seventh portion 33C and the sixth conductor layer 26, there is a portion where different materials do not exist, that is, a portion where the seventh portion 33C and the sixth conductor layer 26 are in direct contact with each other.

As illustrated in FIGS. 19A and 19B, when the height of the first portion 31A is A₁, the height of the second portion 31B is B₁, the height of the fifth portion 33A is A₃, the height of the sixth portion 33B is B₃, the height of the seventh portion 33C is C₃, the height of the first interlayer connection conductor 31 is T₁, and the height of the third interlayer connection conductor 33 is T₃, relationships of T₁<T₃ and B₁/A₁>B₃/(A₃+C₃) are satisfied.

That is, among the first interlayer connection conductor 31 and the third interlayer connection conductor 33, in the third interlayer connection conductor 33 having a large height, a ratio of a portion having low conductivity is smaller than that of the first interlayer connection conductor 31 having a small height. As a result, even when interlayer connection conductors having different heights are included, an increase in the resistance value of the entire interlayer connection conductor can be reduced or prevented.

On the other hand, among the first interlayer connection conductor 31 and the third interlayer connection conductor 33, in the first interlayer connection conductor 31 having a small height, a ratio of a portion having high conductivity is smaller than that of the third interlayer connection conductor 33 having a large height. For example, in a case where the first portion 31A is a plated via and the second portion 31B is a paste via, an increase in manufacturing cost can be reduced or prevented by not forming the first portion 31A more than necessary.

The height B₁ of the second portion 31B is preferably equal to about half of the height B₃ of the sixth portion 33B. As long as the relationships of T₁<T₃ and B₁/A₁>B₃/(A₃+C₃) are satisfied, the height B₁ of the second portion 31B may be greater than about half of the height B₃ of the sixth portion 33B, and may be smaller than about half of the height B₃ of the sixth portion 33B.

The diameter of the first interlayer connection conductor 31 is preferably smaller than the diameter of the third interlayer connection conductor 33. As long as the relationships of T₁<T₃ and B₁/A₁>B₃/(A₃+C₃) are satisfied, the diameter of the first interlayer connection conductor 31 may be equal or substantially equal to the diameter of the third interlayer connection conductor 33, or may be greater than the diameter of the third interlayer connection conductor 33.

The height A₃ of the fifth portion 33A is preferably equal or substantially equal to the height C₃ of the seventh portion 33C, but may be greater than the height C₃ of the seventh portion 33C or smaller than the height C₃ of the seventh portion 33C.

There may be two or more types of the third interlayer connection conductors 33 having the height T₃ and different diameters. In this case, the height A₃ of the fifth portion 33A of the third interlayer connection conductor 33 having a larger diameter is preferably smaller than the height A₃ of the fifth portion 33A of the third interlayer connection conductor 33 having a smaller diameter. Similarly, the height C₃ of the seventh portion 33C of the third interlayer connection conductor 33 having a larger diameter is preferably smaller than the height C₃ of the seventh portion 33C of the third interlayer connection conductor 33 having a smaller diameter.

As long as the relationships of T₁<T₃ and B₁/A₁>B₃/(A₃+C₃) are satisfied, the height A₁ of the first portion 31A may be equal or substantially equal to the height B₁ of the second portion 31B, and may be lower than the height B₁ of the second portion 31B (A₁<B₁), but is preferably higher than the height B₁ of the second portion 31B (A₁>B₁). In particular, when the first interlayer connection conductor 31 has a tapered shape, the connection area between the first portion 31A and the second portion 31B is increased by making the height A₁ of the first portion 31A higher than the height B₁ of the second portion 31B, so that the connection reliability of the first interlayer connection conductor 31 can be improved.

Similarly, as long as the relationships of T₁<T₃ and B₁/A₁>B₃/(A₃+C₃) are satisfied, the height A₃ of the fifth portion 33A may be equal to about half the height B₃ of the sixth portion 33B, and may be lower than about half of the height B₃ of the sixth portion 33B (A₃<B₃/2), but is preferably higher than about half of the height B₃ of the sixth portion 33B (A₃>B₃/2). In particular, when the fifth portion 33A has a tapered shape, the connection area between the fifth portion 33A and the sixth portion 33B is increased by making the height A₃ of the fifth portion 33A higher than about half of the height B₃ of the sixth portion 33B, so that the connection reliability of the third interlayer connection conductor 33 can be improved.

Furthermore, as long as the relationships of T₁<T₃ and B₁/A₁>B₃/(A₃+C₃) are satisfied, the height C₃ of the seventh portion 33C may be equal to about half of the height B₃ of the sixth portion 33B, and may be lower than about half of the height B₃ of the sixth portion 33B (C₃<B₃/2), but is preferably higher than about half of the height B₃ of the sixth portion 33B (C₃>B₃/2). In particular, when the seventh portion 33C has a tapered shape, the connection area between the seventh portion 33C and the sixth portion 33B is increased by making the height C₃ of the seventh portion 33C higher than about half of the height B₃ of the sixth portion 33B, so that the connection reliability of the third interlayer connection conductor 33 can be improved.

The shape of the third interlayer connection conductor 33 is not limited to FIG. 19B.

In the example illustrated in FIG. 19B, the third interlayer connection conductor 33 has a shape in which a set of second interlayer connection conductors 32 (see FIG. 2B) having a tapered shape is connected in an inverted state, but the third interlayer connection conductor 33 may not have a tapered shape.

Although not illustrated in FIG. 19B, at least the interface between the fifth conductor layer 25 and the insulating layer 10 may be provided with a rustproof layer 40 (see FIG. 8B). Similarly, the rustproof layer 40 may be provided at least at the interface between the sixth conductor layer 26 and the insulating layer 10.

In a case where the rustproof layer 40 is disposed at the interface between the fifth conductor layer 25 and the insulating layer 10, the rustproof layer 40 may be in contact with the fifth portion 33A, or may not be in contact with the fifth portion 33A. Similarly, in a case where the rustproof layer 40 is disposed at the interface between the sixth conductor layer 26 and the insulating layer 10, the rustproof layer 40 may be in contact with the seventh portion 33C, or may not be in contact with the seventh portion 33C.

The rustproof layer 40 is preferably not disposed between the fifth portion 33A and the fifth conductor layer 25. Similarly, the rustproof layer 40 is preferably not disposed between the seventh portion 33C and the sixth conductor layer 26.

The surface roughness of the portion of the first conductor layer 21 in contact with the insulating layer 10 may be greater than the surface roughness of the portion of the second conductor layer 22 in contact with the insulating layer 10. In this case, the surface roughness of the fifth conductor layer 25 in contact with the insulating layer 10 may be equal or substantially equal to the surface roughness of the sixth conductor layer 26 in contact with the insulating layer 10, may be greater than the surface roughness of the sixth conductor layer 26 in contact with the insulating layer 10, or may be smaller than the surface roughness of the sixth conductor layer 26 in contact with the insulating layer 10.

The end surface of the fifth portion 33A on the sixth conductor layer 26 side may be flat, may protrude toward the sixth conductor layer 26, or may be recessed toward the fifth conductor layer 25.

The end surface of the seventh portion 33C on the fifth conductor layer 25 side may be flat, may protrude toward the fifth conductor layer 25, or may be recessed toward the sixth conductor layer 26.

The end surface of the fifth portion 33A on the fifth conductor layer 25 side may protrude to the fifth conductor layer 25 side from the interface between the fifth conductor layer 25 and the insulating layer 10.

The end surface of the seventh portion 33C on the sixth conductor layer 26 side may protrude to the sixth conductor layer 26 side from the interface between sixth conductor layer 26 and the insulating layer 10.

The fifth portion 33A may be bonded to the sixth portion 33B with a fifth intermediate layer (not illustrated) interposed therebetween, the fifth intermediate layer including a metal included in the fifth portion 33A and a metal included in the sixth portion 33B, and may be bonded to the fifth conductor layer 25 without the fifth intermediate layer interposed therebetween.

As an example, in the sixth portion 33B, the fifth intermediate layer including Cu and Sn may be provided at the end portion on the fifth portion 33A side. In this case, for example, the fifth intermediate layer is made of a Cu—Sn alloy such as Cu₃Sn or Cu₅Sn. However, the composition of the fifth intermediate layer is different from the composition of the sixth portion 33B.

The seventh portion 33C may be bonded to the sixth portion 33B with a sixth intermediate layer (not illustrated) interposed therebetween, the sixth intermediate layer including a metal included in the seventh portion 33C and a metal included in the sixth portion 33B, and may be bonded to the sixth conductor layer 26 without the sixth intermediate layer interposed therebetween.

As an example, in the sixth portion 33B, the sixth intermediate layer including Cu and Sn may be formed at the end portion on the seventh portion 33C side. In this case, for example, the sixth intermediate layer is made of a Cu—Sn alloy such as Cu₃Sn or Cu₅Sn. However, the composition of the sixth intermediate layer is different from the composition of the sixth portion 33B.

The fifth intermediate layer may or may not extend to the interface between the fifth portion 33A and the insulating layer 10. When the fifth intermediate layer extends to the interface between the fifth portion 33A and the insulating layer 10, the fifth intermediate layer may extend to the interface between the fifth conductor layer 25 and the insulating layer 10.

The sixth intermediate layer may or may not extend to the interface between the seventh portion 33C and the insulating layer 10. When the sixth intermediate layer extends to the interface between the seventh portion 33C and the insulating layer 10, the sixth intermediate layer may extend to the interface between the sixth conductor layer 26 and the insulating layer 10.

The fifth intermediate layer may include one layer or two or more layers. Similarly, the sixth intermediate layer may include one layer or two or more layers.

A portion of the end surface of the fifth portion 33A on the sixth conductor layer 26 side may include a portion protruding toward the sixth conductor layer 26, a portion recessed toward the fifth conductor layer 25, or these portions may be mixed.

A portion of the end surface of the seventh portion 33C on the fifth conductor layer 25 side may include a portion protruding toward the fifth conductor layer 25, a portion recessed toward the sixth conductor layer 26, or these portions may be mixed.

A portion of the sixth portion 33B may be bonded to the fifth conductor layer 25, or may be bonded to the sixth conductor layer 26.

There may be a void inside the fifth portion 33A. Similarly, there may be a void inside the seventh portion 33C. The number, size, and position, for example, of the voids are not limited. In addition to the void or instead of the void, a residue of a resin (carbide) or an oxide of a copper foil (copper oxide) may be present, for example.

The circuit board of the present invention is not limited to the above example embodiments, and various applications and modifications can be made within the scope of the present invention with respect to the configuration and manufacturing conditions, for example, of the circuit board.

The circuit board of the present invention can be used, for example, as a board for a circuit module.

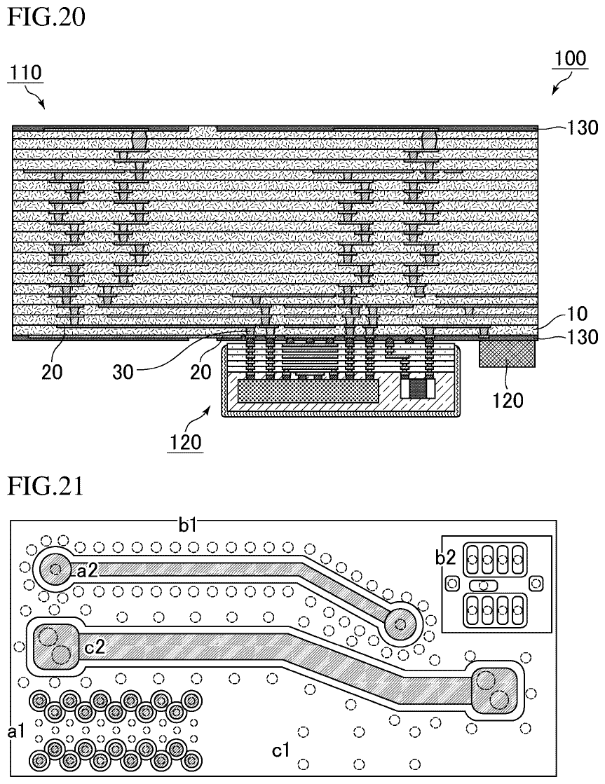

FIG. 20 is a cross-sectional view schematically illustrating an example of a circuit module including the circuit board according to an example embodiment of the present invention.

A circuit module 100 illustrated in FIG. 20 includes a circuit board 110 and an electronic component 120 provided on the circuit board 110.

The circuit board 110 is a circuit board according to an example embodiment of the present invention. The circuit board 110 may be a rigid board or a flexible board. The circuit board 110 may include a bent portion.

The circuit board 110 includes an insulating layer 10, a conductor layer 20, and an interlayer connection conductor 30.

The electronic component 120 is not limited, and is an integrated circuit (IC) or a connector, for example. One or two or more electronic components 120 may be provided on one of the main surfaces of the circuit board 110, and one or two or more electronic components 120 may be provided on both main surfaces of the circuit board 110.

A protective layer 130 may be provided on the surface layer of the circuit board 110. The protective layer 130 is a coverlay or a resist layer, for example. The protective layer 130 may be provided on both main surfaces of the circuit board 110, or may be provided on one of the main surfaces.

In the circuit board 110, the interlayer connection conductor 30 includes a first interlayer connection conductor and a second interlayer connection conductor described in the above example embodiments. The interlayer connection conductor 30 may include a third interlayer connection conductor in addition to the first interlayer connection conductor and the second interlayer connection conductor. Alternatively, the interlayer connection conductor 30 may include the third interlayer connection conductor, instead of the second interlayer connection conductor.

The circuit board 110 may include the interlayer connection conductor 30 other than the first interlayer connection conductor, the second interlayer connection conductor, and the third interlayer connection conductor.

For example, the interlayer connection conductor 30 may include an interlayer connection conductor including only a plated via, may include an interlayer connection conductor including only a paste via, or may include a mixture of these.

As an example, the first interlayer connection conductor described in the above example embodiments may be provided as the interlayer connection conductor 30 inside the insulating layer 10 located on the surface layer of the circuit board 110 on the side (lower side in FIG. 20) where the electronic component 120 is provided. This makes it possible to ensure the connectivity of the interlayer connection conductors even in the fine line portion located on the surface layer.

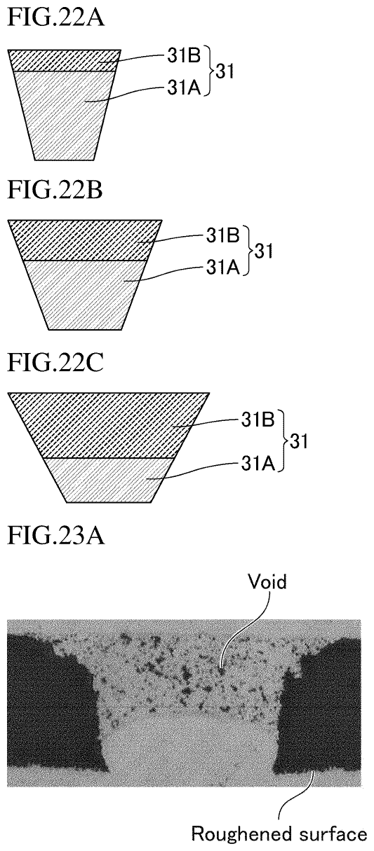

FIG. 21 is a plan view schematically illustrating an example of a surface layer of a circuit board according to an example embodiment of the present invention. FIGS. 22A, 22B, and 22C are cross-sectional views schematically illustrating examples of interlayer connection conductors with a constant height and different diameters.

As illustrated in FIG. 21, interlayer connection conductors a1, a2, b1, b2, c1, and c2 with a constant height and different diameters are provided on the surface layer of the circuit board. When these interlayer connection conductors are the first interlayer connection conductors, as illustrated in FIGS. 22A, 22B, and 22C, the height of the first portion 31A of the first interlayer connection conductor 31 having a larger diameter is preferably smaller than the height of the first portion 31A of the first interlayer connection conductor 31 having a smaller diameter.

In FIG. 21, the interlayer connection conductor a1 connected to the integrated circuit (IC) is expected to be reduced in pitch and diameter. Therefore, the interlayer connection conductor a1 is preferably the first interlayer connection conductor 31 illustrated in FIG. 22A.

In FIG. 21, the interlayer connection conductor a2 connected signal line such as radio frequency (RF) or intermediate frequency (IF), for example, is preferably reduced in diameter for miniaturization. Therefore, the interlayer connection conductor a2 is preferably the first interlayer connection conductor 31 illustrated in FIG. 22A.

In FIG. 21, the interlayer connection conductor b1 provided around the signal line is required to have a relatively small diameter in order to reduce or prevent electric field leakage such as high frequency, for example. Therefore, for example, the interlayer connection conductor b1 is preferably the first interlayer connection conductor 31 illustrated in FIG. 22B.

In FIG. 21, since the land of the terminal of the interlayer connection conductor b2 connected to the connector is relatively large, the diameter of the interlayer connection conductor b2 may also be large. Therefore, for example, the interlayer connection conductor b2 is preferably the first interlayer connection conductor 31 illustrated in FIG. 22B.

In FIG. 21, since the interlayer connection conductor c1 connected to the ground line is connected to a wide land, the diameter of the interlayer connection conductor c1 may also be large. Therefore, for example, the interlayer connection conductor c1 is preferably the first interlayer connection conductor 31 illustrated in FIG. 22C.

In FIG. 21, since a large amount of current flows through the interlayer connection conductor c2 connected to the power supply line, it is required to increase the diameter of the interlayer connection conductor c2 to reduce the resistance. Therefore, for example, the interlayer connection conductor c2 is preferably the first interlayer connection conductor 31 illustrated in FIG. 22C.

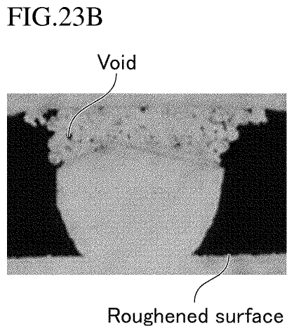

FIGS. 23A and 23B are examples of SEM photographs showing interlayer connection conductors of different heights.

In the examples shown in FIGS. 23A and 23B, the ratio of first portions such as plated vias is different in interlayer connection conductors of different heights.

As shown in FIGS. 23A and 23B, the surface of the lower conductor layer in contact with the insulating layer may be a roughened surface.

In connection with the tenth example embodiment of the present invention, there may be a void inside the second portion, as shown in FIGS. 23A and 23B.

The following content is disclosed in the present specification.

<1>

A circuit board includes an insulating layer including a first main surface and a second main surface facing each other in a thickness direction, a first interlayer connection conductor and a second interlayer connection conductor penetrating a same insulating layer or different insulating layers in the thickness direction, a first conductor layer on the first main surface of the insulating layer and connected to the first interlayer connection conductor, a second conductor layer on the second main surface of the insulating layer and connected to the first interlayer connection conductor, a third conductor layer on the first main surface of the insulating layer and connected to the second interlayer connection conductor, and a fourth conductor layer on the second main surface of the insulating layer and connected to the second interlayer connection conductor, wherein the first interlayer connection conductor includes a first portion and a second portion with lower conductivity than the first portion in the thickness direction, one end portion of the first portion is bonded to the first conductor layer, and an other end portion of the first portion is bonded to one end portion of the second portion, an other end portion of the second portion is bonded to the second conductor layer, the second interlayer connection conductor includes a third portion and a fourth portion with lower conductivity than the third portion in the thickness direction, one end portion of the third portion is bonded to the third conductor layer, and an other end portion of the third portion is bonded to one end portion of the fourth portion, an other end portion of the fourth portion is bonded to the fourth conductor layer, and when a height of the first portion is A₁, a height of the second portion is B₁, a height of the third portion is A₂, a height of the fourth portion is B₂, a height of the first interlayer connection conductor is T₁, and a height of the second interlayer connection conductor is T₂, relationships of T₁<T₂ and B₁/A₁>B₂/A₂ are satisfied.

<2>

The circuit board according to <1>, wherein the height B₁ of the second portion is equal or substantially equal to the height B₂ of the fourth portion.

<3>

The circuit board according to <1> or <2>, wherein a diameter of the first interlayer connection conductor is smaller than a diameter of the second interlayer connection conductor.

<4>

The circuit board according to any one of <1> to <3>, wherein two or more kinds of the first interlayer connection conductors with a height T₁ and different diameters are provided, and a height A of the first portion of the first interlayer connection conductor with a larger diameter is smaller than a height A₁ of the first portion of the first interlayer connection conductor with a smaller diameter.

<5>

The circuit board according to any one of <1> to <4>, wherein a thickness of the insulating layer in which the first interlayer connection conductor is provided is smaller than a thickness of the insulating layer in which the second interlayer connection conductor is provided.

<6>

The circuit board according to any one of <1> to <5>, wherein a surface roughness of the first conductor layer in a portion in contact with the insulating layer is greater than a surface roughness of the second conductor layer in a portion in contact with the insulating layer, and a surface roughness of the third conductor layer in a portion in contact with the insulating layer is greater than a surface roughness of the fourth conductor layer in a portion in contact with the insulating layer.

<7>

The circuit board according to any one of <1> to <6>, wherein the second portion has a tapered shape in which an area of an end surface on the first conductor layer side is smaller than an area of an end surface on the second conductor layer side, and the fourth portion has a tapered shape in which an area of an end surface on the third conductor layer side is smaller than an area of an end surface on the fourth conductor layer side.

<8>

The circuit board according to any one of <1> to <7>, wherein an end surface of the first portion on the second conductor layer side protrudes toward the second conductor layer or is recessed toward the first conductor layer, and an end surface of the third portion on the fourth conductor layer side protrudes toward the fourth conductor layer or is recessed toward the third conductor layer.

<9>

The circuit board according to any one of <1> to <8>, wherein an end surface of the first portion on the first conductor layer side protrudes to the first conductor layer side from an interface between the first conductor layer and the insulating layer, and an end surface of the third portion on the third conductor layer side protrudes to the third conductor layer side from an interface between the third conductor layer and the insulating layer.

<10>

The circuit board according to any one of <1> to <9>, wherein the first portion is bonded to the second portion with a first intermediate layer interposed therebetween, the first intermediate layer including a metal included in the first portion and a metal included in the second portion, and is bonded to the first conductor layer without the first intermediate layer interposed therebetween, the second portion is bonded to the second conductor layer with a second intermediate layer interposed therebetween, the second intermediate layer including a metal included in the second portion and a metal included in the second conductor layer, the third portion is bonded to the fourth portion with a third intermediate layer interposed therebetween, the third intermediate layer including a metal included in the third portion and a metal included in the fourth portion, and is bonded to the third conductor layer without the third intermediate layer interposed therebetween, and the fourth portion is bonded to the fourth conductor layer with a fourth intermediate layer interposed therebetween, the fourth intermediate layer including a metal included in the fourth portion and a metal included in the fourth conductor layer.

<11>

The circuit board according to any one of <1> to <10> further including a third interlayer connection conductor penetrating, in the thickness direction, the insulating layer being the same as or different from the insulating layer provided with the first interlayer connection conductor, a fifth conductor layer on the first main surface of the insulating layer and connected to the third interlayer connection conductor, and a sixth conductor layer on the second main surface of the insulating layer and connected to the third interlayer connection conductor, wherein the third interlayer connection conductor includes a fifth portion, a sixth portion with lower conductivity than the fifth portion, and a seventh portion with higher conductivity than the sixth portion in the thickness direction, one end portion of the fifth portion is bonded to the fifth conductor layer, and an other end portion of the fifth portion is bonded to one end portion of the sixth portion, an other end portion of the sixth portion is bonded to one end portion of the seventh portion, an other end portion of the seventh portion is bonded to the sixth conductor layer, and when a height of the fifth portion is A₃, a height of the sixth portion is B₃, a height of the seventh portion is C₃, and a height of the third interlayer connection conductor is T₃, relationships of T₁<T₃ and B₁/A₁>B₃/(A₃+C₃) are satisfied.

<12>

A circuit board includes an insulating layer including a first main surface and a second main surface facing each other in a thickness direction, a first interlayer connection conductor and a third interlayer connection conductor penetrating a same insulating layer or different insulating layers in the thickness direction, a first conductor layer on the first main surface of the insulating layer and connected to the first interlayer connection conductor, a second conductor layer on the second main surface of the insulating layer and connected to the first interlayer connection conductor, a fifth conductor layer on the first main surface of the insulating layer and connected to the third interlayer connection conductor, and a sixth conductor layer on the second main surface of the insulating layer and connected to the fourth interlayer connection conductor, wherein the first interlayer connection conductor includes a first portion and a second portion with lower conductivity than the first portion in the thickness direction, one end portion of the first portion is bonded to the first conductor layer, and an other end portion of the first portion is bonded to one end portion of the second portion, an other end portion of the second portion is bonded to the second conductor layer, the third interlayer connection conductor includes a fifth portion, a sixth portion with lower conductivity than the fifth portion, and a seventh portion with higher conductivity than the sixth portion in the thickness direction, one end portion of the fifth portion is bonded to the fifth conductor layer, and an other end portion of the fifth portion is bonded to one end portion of the sixth portion, an other end portion of the sixth portion is bonded to one end portion of the seventh portion, an other end portion of the seventh portion is bonded to the sixth conductor layer, and when a height of the first portion is A₁, a height of the second portion is B₁, a height of the fifth portion is A₃, a height of the sixth portion is B₃, a height of the seventh portion is C₃, a height of the first interlayer connection conductor is T₁, and a height of the third interlayer connection conductor is T₃, relationships of T₁<T₃ and B₁/A₁>B₃/(A₃+C₃) are satisfied.

<13>

The circuit board according to <11> or <12>, wherein the height B₁ of the second portion is equal to about half of the height B₃ of the sixth portion.

<14>

The circuit board according to any one of <11> to <13>, wherein the height A₃ of the fifth portion is equal or substantially equal to the height C₃ of the seventh portion.

<15>

The circuit board according to any one of <11> to <14>, wherein a diameter of the first interlayer connection conductor is smaller than a diameter of the third interlayer connection conductor.

<16>

The circuit board according to any one of <1> to <15>, wherein the insulating layer includes a thermoplastic resin as a main component.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit board comprising:
an insulating layer including a first main surface and a second main surface facing each other in a thickness direction;
a first interlayer connection conductor and a second interlayer connection conductor penetrating a same insulating layer or different insulating layers in the thickness direction;
a first conductor layer on the first main surface of the insulating layer and connected to the first interlayer connection conductor;
a second conductor layer on the second main surface of the insulating layer and connected to the first interlayer connection conductor;
a third conductor layer on the first main surface of the insulating layer and connected to the second interlayer connection conductor; and
a fourth conductor layer on the second main surface of the insulating layer and connected to the second interlayer connection conductor; wherein
the first interlayer connection conductor includes a first portion and a second portion with lower conductivity than the first portion in the thickness direction;
one end portion of the first portion is bonded to the first conductor layer, and an other end portion of the first portion is bonded to one end portion of the second portion;
an other end portion of the second portion is bonded to the second conductor layer;
the second interlayer connection conductor includes a third portion and a fourth portion with lower conductivity than the third portion in the thickness direction;
one end portion of the third portion is bonded to the third conductor layer, and an other end portion of the third portion is bonded to one end portion of the fourth portion;
an other end portion of the fourth portion is bonded to the fourth conductor layer; and
when a height of the first portion is A₁, a height of the second portion is B₁, a height of the third portion is A₂, a height of the fourth portion is B₂, a height of the first interlayer connection conductor is T₁, and a height of the second interlayer connection conductor is T₂, relationships of T₁<T₂ and B₁/A₁>B₂/A₂ are satisfied.

2. The circuit board according to claim 1, wherein the height B₁ of the second portion is equal or substantially equal to the height B₂ of the fourth portion.

3. The circuit board according to claim 1, wherein a diameter of the first interlayer connection conductor is smaller than a diameter of the second interlayer connection conductor.

4. The circuit board according to claim 1, wherein
two or more kinds of the first interlayer connection conductors with a height T₁ and different diameters are provided; and
a height A₁ of the first portion of the first interlayer connection conductor with a larger diameter is smaller than a height A₁ of the first portion of the first interlayer connection conductor with a smaller diameter.

5. The circuit board according to claim 1, wherein a thickness of the insulating layer in which the first interlayer connection conductor is provided is smaller than a thickness of the insulating layer in which the second interlayer connection conductor is provided.

6. The circuit board according to claim 1, wherein
a surface roughness of the first conductor layer in a portion in contact with the insulating layer is greater than a surface roughness of the second conductor layer in a portion in contact with the insulating layer; and
a surface roughness of the third conductor layer in a portion in contact with the insulating layer is greater than a surface roughness of the fourth conductor layer in a portion in contact with the insulating layer.

7. The circuit board according to claim 1, wherein
the second portion has a tapered shape in which an area of an end surface on the first conductor layer side is smaller than an area of an end surface on the second conductor layer side; and
the fourth portion has a tapered shape in which an area of an end surface on the third conductor layer side is smaller than an area of an end surface on the fourth conductor layer side.

8. The circuit board according to claim 1, wherein
an end surface of the first portion on the second conductor layer side protrudes toward the second conductor layer or is recessed toward the first conductor layer; and
an end surface of the third portion on the fourth conductor layer side protrudes toward the fourth conductor layer or is recessed toward the third conductor layer.

9. The circuit board according to claim 1, wherein
an end surface of the first portion on the first conductor layer side protrudes to the first conductor layer side from an interface between the first conductor layer and the insulating layer; and
an end surface of the third portion on the third conductor layer side protrudes to the third conductor layer side from an interface between the third conductor layer and the insulating layer.

10. The circuit board according to claim 1, wherein
the first portion is bonded to the second portion with a first intermediate layer interposed therebetween, the first intermediate layer including a metal included in the first portion and a metal included in the second portion, and is bonded to the first conductor layer without the first intermediate layer interposed therebetween;
the second portion is bonded to the second conductor layer with a second intermediate layer interposed therebetween, the second intermediate layer including a metal included in the second portion and a metal included in the second conductor layer;
the third portion is bonded to the fourth portion with a third intermediate layer interposed therebetween, the third intermediate layer including a metal included in the third portion and a metal included in the fourth portion, and is bonded to the third conductor layer without the third intermediate layer interposed therebetween; and
the fourth portion is bonded to the fourth conductor layer with a fourth intermediate layer interposed therebetween, the fourth intermediate layer including a metal included in the fourth portion and a metal included in the fourth conductor layer.

11. The circuit board according to claim 1, further comprising:
a third interlayer connection conductor penetrating, in the thickness direction, the insulating layer being the same as or different from the insulating layer provided with the first interlayer connection conductor;
a fifth conductor layer on the first main surface of the insulating layer and connected to the third interlayer connection conductor; and
a sixth conductor layer on the second main surface of the insulating layer and connected to the third interlayer connection conductor; wherein
the third interlayer connection conductor includes a fifth portion, a sixth portion with lower conductivity than the fifth portion, and a seventh portion with higher conductivity than the sixth portion in the thickness direction;
one end portion of the fifth portion is bonded to the fifth conductor layer, and an other end portion of the fifth portion is bonded to one end portion of the sixth portion;
an other end portion of the sixth portion is bonded to one end portion of the seventh portion;
an other end portion of the seventh portion is bonded to the sixth conductor layer; and
when a height of the fifth portion is A₃, a height of the sixth portion is B₃, a height of the seventh portion is C₃, and a height of the third interlayer connection conductor is T₃, relationships of T₁<T₃ and B₁/A₁>B₃/(A₃+C₃) are satisfied.

12. The circuit board according to claim 1, wherein the insulating layer includes a thermoplastic resin as a main component.

13. The circuit board according to claim 12, wherein the thermoplastic resin includes a liquid crystal polymer, a fluororesin, a thermoplastic polyimide resin, a polyether ether ketone resin, or a polyphenylene sulfide resin.

14. A circuit board comprising:
an insulating layer including a first main surface and a second main surface facing each other in a thickness direction;
a first interlayer connection conductor and a third interlayer connection conductor penetrating a same insulating layer or different insulating layers in the thickness direction;
a first conductor layer on the first main surface of the insulating layer and connected to the first interlayer connection conductor;
a second conductor layer on the second main surface of the insulating layer and connected to the first interlayer connection conductor;
a fifth conductor layer on the first main surface of the insulating layer and connected to the third interlayer connection conductor; and
a sixth conductor layer on the second main surface of the insulating layer and connected to the fourth interlayer connection conductor; wherein
the first interlayer connection conductor includes a first portion and a second portion with lower conductivity than the first portion in the thickness direction;
one end portion of the first portion is bonded to the first conductor layer, and an other end portion of the first portion is bonded to one end portion of the second portion;
an other end portion of the second portion is bonded to the second conductor layer;
the third interlayer connection conductor includes a fifth portion, a sixth portion with lower conductivity than the fifth portion, and a seventh portion with higher conductivity than the sixth portion in the thickness direction;
one end portion of the fifth portion is bonded to the fifth conductor layer, and an other end portion of the fifth portion is bonded to one end portion of the sixth portion;
an other end portion of the sixth portion is bonded to one end portion of the seventh portion;
an other end portion of the seventh portion is bonded to the sixth conductor layer; and
when a height of the first portion is A₁, a height of the second portion is B₁, a height of the fifth portion is A₃, a height of the sixth portion is B₃, a height of the seventh portion is C₃, a height of the first interlayer connection conductor is T₁, and a height of the third interlayer connection conductor is T₃, relationships of T₁<T₃ and B₁/A₁>B₃/(A₃+C₃) are satisfied.

15. The circuit board according to claim 14, wherein the height B₁ of the second portion is equal to about half of the height B₃ of the sixth portion.

16. The circuit board according to claim 14, wherein the height A₃ of the fifth portion is equal or substantially equal to the height C₃ of the seventh portion.

17. The circuit board according to claim 14, wherein a diameter of the first interlayer connection conductor is smaller than a diameter of the third interlayer connection conductor.

18. The circuit board according to claim 14, wherein the insulating layer includes a thermoplastic resin as a main component.

19. The circuit board according to claim 18, wherein the thermoplastic resin includes a liquid crystal polymer, a fluororesin, a thermoplastic polyimide resin, a polyether ether ketone resin, or a polyphenylene sulfide resin.
